(19) United States
(12) Patent Application Publication
(10) Pub. No.: US 2011/0062016 A1
(43) Pub. Date: Mar. 17, 2011

(54) METHOD FOR MANUFACTURING ALUMINUM-CONTAINING NITRIDE INTERMEDIATE LAYER, METHOD FOR MANUFACTURING NITRIDE LAYER, AND METHOD FOR MANUFACTURING NITRIDE SEMICONDUCTOR ELEMENT

(75) Inventors: Masahiro ARAKI, Osaka-shi (JP); Takaaki Utsumi, Osaka-shi (JP); Masahiko Sakata, Osaka-shi (JP)

(73) Assignee: Sharp Kabushiki Kaisha, Osaka-shi (JP)

(21) Appl. No.: 12/854,715

(22) Filed: Aug. 11, 2010

(30) Foreign Application Priority Data
Sep. 11, 2009 (JP) 2009-210382

(51) Int. Cl. C23C 14/35

(52) U.S. Cl. 204/192.25

(57) ABSTRACT

There is provided a method for manufacturing an aluminum-containing nitride intermediate layer, a method for manufacturing a nitride layer, and a method for manufacturing a nitride semiconductor element by using the nitride layer, in which at least one of the following conditions (i) to (iii) is employed during stacking of the aluminum-containing nitride intermediate layer by using a DC magnetron sputtering method in which a voltage is applied by means of a DC-continuous scheme.

(i) The shortest distance between a center of a surface of a target and a growth surface of a substrate is set to 100 mm or more and 250 mm or less.
(ii) Nitrogen gas is used as gas supplied to a DC magnetron sputtering apparatus.
(iii) The target is inclined with respect to the growth surface of the substrate.

This nonprovisional application is based on Japanese Patent Application No. 2009-210382 filed on Sep. 11, 2009, with the Japan Patent Office, the entire contents of which are hereby incorporated by reference.

### BACKGROUND OF THE INVENTION

1. Field of the Invention

The present invention relates to a method for manufacturing an aluminum-containing nitride intermediate layer, a method for manufacturing a nitride layer, and a method for manufacturing a nitride semiconductor element.

2. Description of the Background Art

Since a III-V group compound semiconductor (III group nitride semiconductor) including nitrogen has a bandgap corresponding to the energy of light having a wavelength in the infrared to ultraviolet region, the III-V group compound semiconductor is useful as materials for a light-emitting element that emits light having a wavelength in the infrared to ultraviolet region and a light-receiving element that receives light having a wavelength in that region.

In addition, in the III group nitride semiconductor, binding between atoms that configure the III group nitride semiconductor is strong, the dielectric breakdown voltage is high, and the saturation electron speed is high. Therefore, the III group nitride semiconductor is also useful as a material for an electronic device such as a high-temperature-resistant, high-power and high-frequency transistor.

Furthermore, the III group nitride semiconductor is also receiving attention as a material that hardly damages the environment and is easy to handle.

In order to fabricate a practical nitride semiconductor element by using the III group nitride semiconductor that is the excellent material as described above, it is necessary to stack, on a prescribed substrate, a III group nitride semiconductor layer formed of a thin film of the III group nitride semiconductor to form a prescribed element structure.

It is the most suitable to use, as the substrate, a substrate formed of the III group nitride semiconductor having a lattice constant and a thermal expansion coefficient that allow the III group nitride semiconductor to grow directly on the substrate. For example, a gallium nitride (GaN) substrate or the like is preferably used as the substrate formed of the III group nitride semiconductor.

At present, however, the dimension of the GaN substrate is small, that is, the diameter thereof is two inches or less. In addition, the GaN substrate is very expensive. Therefore, the GaN substrate is not practical.

For this reason, at present, a sapphire substrate, a silicon carbide (SiC) substrate or the like having a large difference in lattice constant and thermal expansion coefficient as compared with the III group nitride semiconductor is used as the substrate for fabricating the nitride semiconductor element.

There exists a difference in lattice constant of about 16% between the sapphire substrate and GaN that is a typical III group nitride semiconductor. In addition, there exists a difference in lattice constant of about 6% between the SiC substrate and GaN. When such large difference in lattice constant exists between the substrate and the III group nitride semiconductor that grows on the substrate, it is generally difficult to epitaxially grow a crystal formed of the III group nitride semiconductor on the substrate. For example, when a GaN crystal is epitaxially grown directly on the sapphire substrate, there is a problem that three-dimensional growth of the GaN crystal cannot be avoided and the GaN crystal having a flat surface cannot be obtained.

Thus, a layer referred to as a so-called buffer layer for eliminating the difference in lattice constant between the substrate and the III group nitride semiconductor is generally formed between the substrate and the III group nitride semiconductor.

Japanese Patent Laying-Open No. 02-229476 (Patent Document 1), for example, discloses a method for forming a buffer layer of AlN on a sapphire substrate by using an MOVPE method, and then, growing a III group nitride semiconductor made of AlₓGa₁₋ₓN.

In the method disclosed in Patent Document 1 as well, however, it has been difficult to obtain the buffer layer of AlN having a flat surface with good reproducibility. This is supposed to be because, when the buffer layer of AlN is formed by using the MOVPE method, trimethylaluminum (TMA) gas and ammonia (NH₃) gas used as material gases react readily in the vapor phase.

Accordingly, in the method disclosed in Patent Document 1, it has been difficult to grow, on the buffer layer of AlN, the high-quality III group nitride semiconductor made of AlₓGa₁₋ₓN that has a flat surface and low defect density, with good reproducibility.

In addition, Japanese Patent Laying-Open No. 60-173829 (Patent Document 2), for example, discloses a method for forming an AlₓGa₁₋ₓN (0≦x≦1) buffer layer by using a high-frequency sputtering method in which a DC bias is applied onto a sapphire substrate.

A III group nitride semiconductor formed on the AlₓGa₁₋ₓN (0≦x≦1) buffer layer by using the method disclosed in Patent Document 2, however, has not have excellent crystallinity as disclosed in paragraph [0004] of Japanese Patent Laying-Open No. 2000-286202 (Patent Document 3) and paragraph [0004] of Japanese Patent Laying-Open No. 2001-094150 (Patent Document 4).

Thus, Patent Document 3 proposes a method for heat-treating a buffer layer formed of a III group nitride semiconductor formed by using a DC magnetron sputtering method, under the atmosphere of a mixed gas of hydrogen gas and ammonia gas. In addition, Patent Document 4 proposes a method for forming a buffer layer formed of a III group nitride semiconductor and having a film thickness of 50 angstroms or more and 3000 angstroms or less, on a sapphire substrate having a temperature raised to 400° C. or more, by using a DC magnetron sputtering method.

Furthermore, Japanese Patent Laying-Open No. 2008-034444 (Patent Document 5) proposes a method for forming a buffer layer formed of columnar AlN crystals on a sapphire substrate heated to 750° C., by using a high-frequency sputtering method.

### SUMMARY OF THE INVENTION

Nevertheless, even when the buffer layer formed of the III group nitride semiconductor is formed by using the methods disclosed in above Patent Documents 3 to 5 and the III group nitride semiconductor layer is formed on the buffer layer, the III group nitride semiconductor layer having excellent crystallinity has not been able to be formed with good reproducibility. As a result, the nitride semiconductor element having excellent characteristics has not been able to be fabricated with good reproducibility.

In light of the above circumstances, an object of the present invention is to provide a method for manufacturing an aluminum-containing nitride intermediate layer on which a nitride layer having excellent crystallinity can be formed with good reproducibility, a method for manufacturing the nitride layer, and a method for manufacturing a nitride semiconductor element by using the nitride layer.

According to a first aspect of the present invention, there can be provided a method for manufacturing an aluminum-containing nitride intermediate layer, including the steps of: arranging a substrate and a target containing aluminum to have a distance of 100 mm or more and 250 mm or less between the substrate and the target; and forming an aluminum-containing nitride intermediate layer on a surface of the substrate by using a DC magnetron sputtering method in which a voltage is applied between the substrate and the target by means of a DC-continuous scheme.

Preferably, the method for manufacturing an aluminum-containing nitride intermediate layer according to the first aspect of the present invention further includes the step of, between the step of arranging the substrate and the target and the step of forming the aluminum-containing nitride intermediate layer, introducing nitrogen gas between the substrate and the target.

In addition, preferably, in the method for manufacturing an aluminum-containing nitride intermediate layer according to the first aspect of the present invention, in the step of arranging the substrate and the target, the substrate and the target are arranged such that the target is inclined with respect to the substrate.

According to a second aspect of the present invention, there can be provided a method for manufacturing an aluminum-containing nitride intermediate layer, including the steps of: arranging a substrate and a target containing aluminum to have a spacing between the substrate and the target; introducing nitrogen gas between the substrate and the target; and forming an aluminum-containing nitride intermediate layer on a surface of the substrate by using a DC magnetron sputtering method in which a voltage is applied between the substrate and the target by means of a DC-continuous scheme.

Preferably, in the method for manufacturing an aluminum-containing nitride intermediate layer according to the second aspect of the present invention, in the step of arranging the substrate and the target, the substrate and the target are arranged such that the target is inclined with respect to the substrate.

According to a third aspect of the present invention, there can be provided a method for manufacturing an aluminum-containing nitride intermediate layer, including the steps of arranging a substrate and a target containing aluminum to have a spacing between the substrate and the target and to incline the target with respect to the substrate; and forming an aluminum-containing nitride intermediate layer on a surface of the substrate by using a DC magnetron sputtering method in which a voltage is applied between the substrate and the target by means of a DC-continuous scheme.

According to a fourth aspect of the present invention, there can be provided a method for manufacturing a nitride layer, including the steps of: arranging a substrate and a target containing aluminum to have a distance of 100 mm or more and 250 mm or less between the substrate and the target; forming an aluminum-containing nitride intermediate layer on a surface of the substrate by using a DC magnetron sputtering method in which a voltage is applied between the substrate and the target by means of a DC-continuous scheme; and forming a nitride layer on the aluminum-containing nitride intermediate layer.

Preferably, the method for manufacturing a nitride layer according to the fourth aspect of the present invention further includes the step of between the step of arranging the substrate and the target and the step of forming the aluminum-containing nitride intermediate layer, introducing nitrogen gas between the substrate and the target.

In addition, preferably, in the method for manufacturing a nitride layer according to the fourth aspect of the present invention, in the step of arranging the substrate and the target, the substrate and the target are arranged such that the target is inclined with respect to the substrate.

According to a fifth aspect of the present invention, there can be provided a method for manufacturing a nitride layer, including the steps of: arranging a substrate and a target containing aluminum to have a spacing between the substrate and the target; introducing nitrogen gas between the substrate and the target; forming an aluminum-containing nitride intermediate layer on a surface of the substrate by using a DC magnetron sputtering method in which a voltage is applied between the substrate and the target by means of a DC-continuous scheme; and forming a nitride layer on the aluminum-containing nitride intermediate layer.

Preferably, in the method for manufacturing a nitride layer according to the fifth aspect of the present invention, in the step of arranging the substrate and the target, the substrate and the target are arranged such that the target is inclined with respect to the substrate.

According to a sixth aspect of the present invention, there can be provided a method for manufacturing a nitride layer, including the steps of: arranging a substrate and a target containing aluminum to have a spacing between the substrate and the target and to incline the target with respect to the substrate; forming an aluminum-containing nitride intermediate layer on a surface of the substrate by using a DC magnetron sputtering method in which a voltage is applied between the substrate and the target by means of a DC-continuous scheme; and forming a nitride layer on the aluminum-containing nitride intermediate layer.

According to a seventh aspect of the present invention, there can be provided a method for manufacturing a nitride semiconductor element, including the steps of: arranging a substrate and a target containing aluminum to have a distance of 100 mm or more and 250 mm or less between the substrate and the target; forming an aluminum-containing nitride intermediate layer on a surface of the substrate by using a DC magnetron sputtering method in which a voltage is applied between the substrate and the target by means of a DC-continuous scheme; and forming a nitride semiconductor layer on the aluminum-containing nitride intermediate layer.

Preferably, the method for manufacturing a nitride semiconductor element according to the seventh aspect of the present invention further includes the step of, between the step of arranging the substrate and the target and the step of forming the aluminum-containing nitride intermediate layer, introducing nitrogen gas between the substrate and the target.

In addition, preferably, in the method for manufacturing a nitride semiconductor element according to the seventh aspect of the present invention, in the step of arranging the substrate and the target, the substrate and the target are arranged such that the target is inclined with respect to the substrate.

According to an eighth aspect of the present invention, there can be provided a method for manufacturing a nitride semiconductor element, including the steps of: arranging a substrate and a target containing aluminum to have a spacing between the substrate and the target; introducing nitrogen gas between the substrate and the target; forming an aluminum-containing nitride intermediate layer on a surface of the substrate by using a DC magnetron sputtering method in which a voltage is applied between the substrate and the target by means of a DC-continuous scheme; and forming a nitride semiconductor layer on the aluminum-containing nitride intermediate layer.

Preferably, in the method for manufacturing a nitride semiconductor element according to the eighth aspect of the present invention, in the step of arranging the substrate and the target, the substrate and the target are arranged such that the target is inclined with respect to the substrate.

According to a ninth aspect of the present invention, there can be provided a method for manufacturing a nitride semiconductor element, including the steps of: arranging a substrate and a target containing aluminum to have a spacing between the substrate and the target and to incline the target with respect to the substrate; forming an aluminum-containing nitride intermediate layer on a surface of the substrate by using a DC magnetron sputtering method in which a voltage is applied between the substrate and the target by means of a DC-continuous scheme; and forming a nitride semiconductor layer on the aluminum-containing nitride intermediate layer.

According to the present invention, there can be provided a method for manufacturing an aluminum-containing nitride intermediate layer on which a nitride layer having excellent crystallinity can be formed with good reproducibility, a method for manufacturing the nitride layer, and a method for manufacturing a nitride semiconductor element by using the nitride layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a nitride semiconductor light-emitting diode element of a first embodiment that is an example of a nitride semiconductor element of the present invention.

FIG. 2 is a schematic cross-sectional view illustrating a part of a manufacturing process in an example of a method for manufacturing the nitride semiconductor light-emitting diode element of the first embodiment.

FIG. 3 is a schematic configuration diagram of an example of a DC magnetron sputtering apparatus used to stack an aluminum-containing nitride intermediate layer on a surface of a substrate.

FIG. 4 is a schematic configuration diagram of another example of the DC magnetron sputtering apparatus used to stack the aluminum-containing nitride intermediate layer on the surface of the substrate.

FIG. 5 is a schematic configuration diagram of still another example of the DC magnetron sputtering apparatus used to stack the aluminum-containing nitride intermediate layer on the surface of the substrate.

FIG. 6 is a schematic cross-sectional view illustrating a part of the manufacturing process in the example of the method for manufacturing the nitride semiconductor light-emitting diode element of the first embodiment.

FIG. 7 is a schematic cross-sectional view illustrating a part of the manufacturing process in the example of the method for manufacturing the nitride semiconductor light-emitting diode element of the first embodiment.

FIG. 8 is a schematic cross-sectional view illustrating a part of the manufacturing process in the example of the method for manufacturing the nitride semiconductor light-emitting diode element of the first embodiment.

FIG. 9 is a schematic cross-sectional view of an example of a light-emitting apparatus in which the nitride semiconductor light-emitting diode element of the first embodiment is used.

FIG. 10 is a schematic cross-sectional view of a nitride semiconductor laser element of a second embodiment that is another example of the nitride semiconductor element of the present invention.

FIG. 11 is a schematic cross-sectional view illustrating a part of a manufacturing process in an example of a method for manufacturing the nitride semiconductor laser element of the second embodiment.

FIG. 12 is a schematic cross-sectional view illustrating a part of the manufacturing process in the example of the method for manufacturing the nitride semiconductor laser element of the second embodiment.

FIG. 13 is a schematic cross-sectional view of a nitride semiconductor transistor element of a third embodiment that is another example of the nitride semiconductor element of the present invention.

FIG. 14 is a schematic cross-sectional view illustrating a part of a manufacturing process in an example of a method for manufacturing the nitride semiconductor transistor element of the third embodiment.

FIG. 15 is a schematic cross-sectional view illustrating a part of a manufacturing process in a method for manufacturing a nitride semiconductor light-emitting diode element of Experimental Examples 1 to 15.

FIG. 16 is a schematic configuration diagram of a DC magnetron sputtering apparatus used to form an AlN buffer layer in Experimental Examples 1 to 8 and 13 to 15.

FIG. 17 is a schematic cross-sectional view illustrating a part of the manufacturing process in the method for manufacturing the nitride semiconductor light-emitting diode element of Experimental Examples 1 to 15.

FIG. 18 is a schematic cross-sectional view illustrating a part of the manufacturing process in the method for manufacturing the nitride semiconductor light-emitting diode element of Experimental Examples 1 to 15.

FIG. 19 is a schematic cross-sectional view illustrating a part of the manufacturing process in the method for manufacturing the nitride semiconductor light-emitting diode element of Experimental Examples 1 to 15.

FIG. 20 is a schematic cross-sectional view illustrating a part of the manufacturing process in the method for manufacturing the nitride semiconductor light-emitting diode element of Experimental Examples 1 to 15.

FIG. 21 is a schematic cross-sectional view illustrating a part of the manufacturing process in the method for manufacturing the nitride semiconductor light-emitting diode element of Experimental Examples 1 to 15.

FIG. 22 is a schematic configuration diagram of a DC magnetron sputtering apparatus used to form the AlN buffer layer in Experimental Examples 9 to 12.

FIG. 23 illustrates the relationship between the half value width (arcsec) of an X-ray rocking curve in a (004) plane of a GaN underlying layer and the shortest distance d (mm) between a center of a surface of an Al target and a c plane of a sapphire substrate.

### DESCRIPTION OF THE PREFERRED EMBODIMENTS

Embodiments of the present invention will be described hereinafter. It is noted that the same reference characters indicate the same or corresponding portions in the drawings of the present invention.

### First Embodiment

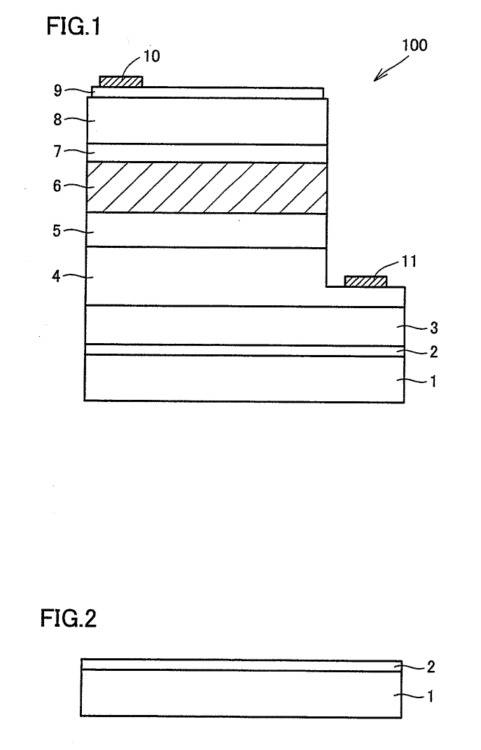

FIG. 1 shows a schematic cross-sectional view of a nitride semiconductor light-emitting diode element of a first embodiment that is an example of a nitride semiconductor element of the present invention.

A nitride semiconductor light-emitting diode element 100 of the first embodiment includes: a substrate 1; an aluminum-containing nitride intermediate layer 2 placed in contact with a surface of substrate 1; a nitride semiconductor underlying layer 3 placed in contact with a surface of aluminum-containing nitride intermediate layer 2; an n-type nitride semiconductor contact layer 4 placed in contact with a surface of nitride semiconductor underlying layer 3; an n-type nitride semiconductor clad layer 5 placed in contact with a surface of n-type nitride semiconductor contact layer 4; a nitride semiconductor active layer 6 placed in contact with a surface of n-type nitride semiconductor clad layer 5; a p-type nitride semiconductor clad layer 7 placed in contact with a surface of nitride semiconductor active layer 6; a p-type nitride semiconductor contact layer 8 placed in contact with a surface of p-type nitride semiconductor clad layer 7; and a translucent electrode layer 9 placed in contact with a surface of p-type nitride semiconductor contact layer 8. An n-side electrode 11 is placed to be in contact with an exposed surface of n-type nitride semiconductor contact layer 4, and a p-side electrode 10 is placed to be in contact with a surface of translucent electrode layer 9.

An example of a method for manufacturing nitride semiconductor light-emitting diode element 100 of the first embodiment will be described hereinafter.

First, as shown in a schematic cross-sectional view in FIG. 2, aluminum-containing nitride intermediate layer 2 is stacked on the surface of substrate 1. Aluminum-containing nitride intermediate layer 2 is formed by using a DC magnetron sputtering method in which a voltage is applied between substrate 1 and a target by means of a DC-continuous scheme.

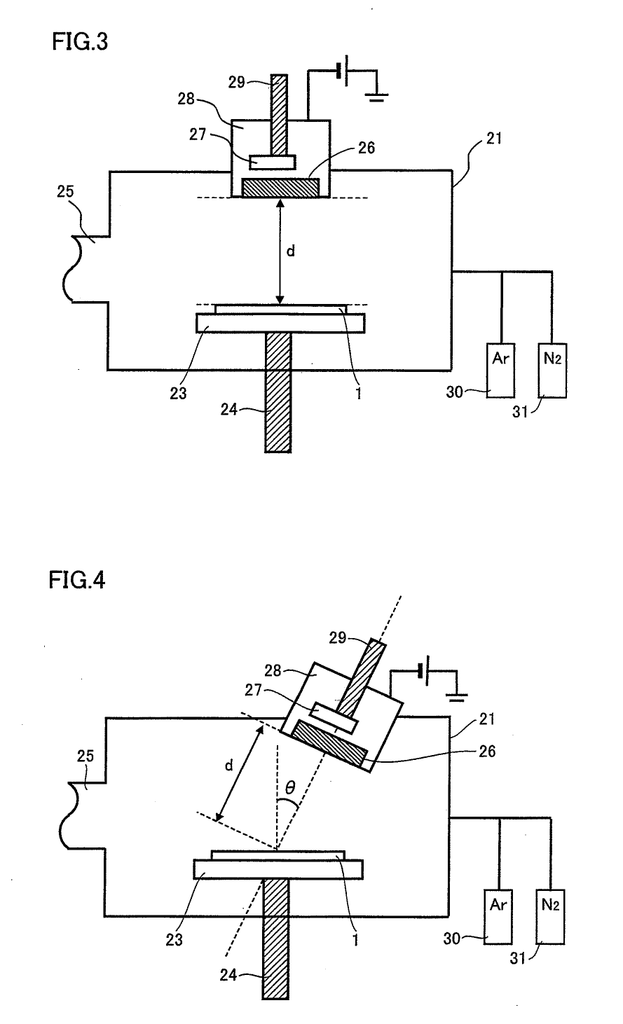

FIG. 3 illustrates a schematic configuration of an example of a DC magnetron sputtering apparatus used to stack aluminum-containing nitride intermediate layer 2 on the surface of substrate 1.

The DC magnetron sputtering apparatus includes: a chamber 21; a heater 23 placed at the lower part inside chamber 21; a cathode 28 placed to face heater 23; and an exhaust port 25 for discharging gas inside chamber 21 to outside chamber 21.

It is noted that heater 23 is supported by a heater support 24. Cathode 28 has an Al target 26 made of aluminum and a magnet 27 supported by a magnet support 29. An Ar gas supply pipe 30 for supplying argon gas into chamber 21, and an N₂ gas supply pipe 31 for supplying nitrogen gas into chamber 21 are connected to chamber 21.

For stacking of aluminum-containing nitride intermediate layer 2 on the surface of substrate 1, substrate 1 is first placed on heater 23 inside the DC magnetron sputtering apparatus having the above configuration. Substrate 1 is arranged to have a prescribed distance d such that a growth surface of substrate 1 (a surface where aluminum-containing nitride intermediate layer 2 grows) faces a surface of Al target 26.

As substrate 1, a substrate having an exposed surface such as the a plane, c plane, m plane, or r plane and made of a sapphire (Al₂O₃) single crystal, a spinel (MgAl₂O₄) single crystal, a ZnO single crystal, a LiAlO₂ single crystal, a LiGaO₂ single crystal, a MgO single crystal, a Si single crystal, a SiC single crystal, a GaAs single crystal, an AlN single crystal, a GaN single crystal, or a boride single crystal such as ZrB₂, and the like can be used. It is noted that the surface orientation of the growth surface of substrate 1 is not particularly limited, and a just substrate, a substrate to which an off angle is provided, and the like can be used as appropriate. In particular, the use of a sapphire substrate made of the sapphire single crystal as substrate 1 is preferable because, when the sapphire substrate made of the sapphire single crystal is used as substrate 1 and aluminum-containing nitride intermediate layer 2 that will be described later is formed on the c plane of the sapphire substrate, there is an increasing tendency to allow stacking of aluminum-containing nitride intermediate layer 2 having excellent crystallinity and formed of an aggregate of columnar crystals each having an array of crystal grains.

Above distance d indicates the shortest distance between a center of the surface of Al target 26 and the growth surface of substrate 1. Distance d is preferably set to 100 mm or more and 250 mm or less, more preferably 120 mm or more and 210 mm or less, and still more preferably 150 mm or more and 180 mm or less. When aluminum-containing nitride intermediate layer 2 is stacked by using the DC magnetron sputtering method, high-energy reactive species are supplied to substrate 1. When above distance d is set to 100 mm or more, damage to the growth surface of substrate 1 caused by the above reactive species can be decreased. When above distance d is set to 250 mm or less, plasma discharge readily occurs and the formation speed of aluminum-containing nitride intermediate layer 2 is increased. Therefore, there is a tendency to allow stacking of aluminum-containing nitride intermediate layer 2 having excellent crystallinity and formed of the aggregate of columnar crystals each having the array of crystal grains that extend in a direction (perpendicular direction) normal to the growth surface of substrate 1. Accordingly, by growing a nitride layer on the surface of such aluminum-containing nitride intermediate layer 2 having excellent crystallinity, a nitride layer (nitride semiconductor underlying layer 3 in the present embodiment) having low dislocation density and excellent crystallinity can be obtained with good reproducibility, and in turn, a nitride semiconductor element having excellent characteristics can be fabricated with good reproducibility.

When above distance d is set to 120 mm or more and 210 mm or less, in particular 150 mm or more and 180 mm or less, aluminum-containing nitride intermediate layer 2 having more excellent crystallinity can be stacked. Therefore, there is an increasing tendency to allow growth, with good reproducibility, of the nitride layer having lower dislocation density and more excellent crystallinity on the surface of such aluminum-containing nitride intermediate layer 2, and in turn, there is an increasing tendency to allow fabrication of the nitride semiconductor element having more excellent characteristics with good reproducibility.

Next, the argon gas is supplied from Ar gas supply pipe 30 into chamber 21 and the nitrogen gas is supplied from N₂ gas supply pipe 31 into chamber 21, thereby introducing the argon gas and the nitrogen gas between substrate 1 and Al target 26. Then, a voltage is applied between substrate 1 and Al target 26 by means of the DC-continuous scheme to generate plasma of the argon gas and the nitrogen gas between substrate 1 and Al target 26. As a result, by sputtering of Al target 26, aluminum-containing nitride intermediate layer 2 made of a compound of aluminum and nitrogen is stacked on the surface of substrate 1. It is noted that the DC-continuous scheme is a scheme to continuously apply a DC voltage (voltage whose direction does not vary depending on time) having a prescribed magnitude between substrate 1 and Al target 26 during sputtering of Al target 26.

The volume ratio of the nitrogen gas (the ratio of nitrogen: %) to the gas supplied into chamber 21 is preferably 50% or more, more preferably 75% or more, and the most preferably 100% (only the nitrogen gas is supplied). When the above ratio of nitrogen is set to 50% or more, in particular 75% or more, the amount of impurities taken into aluminum-containing nitride intermediate layer 2 can be suppressed, and thus, the crystallinity of aluminum-containing nitride intermediate layer 2 can be enhanced. In addition, when the above ratio of nitrogen is 100%, only the nitrogen gas is supplied into chamber 21, and thus, the crystallinity of aluminum-containing nitride intermediate layer 2 can be more significantly enhanced. When the nitride layer is grown on the surface of aluminum-containing nitride intermediate layer 2 having excellent crystallinity as described above, there is a tendency to obtain the nitride layer having low dislocation density and excellent crystallinity with good reproducibility, and in turn, there is an increasing tendency to allow fabrication of the nitride semiconductor element having excellent characteristics with good reproducibility.

Although the case has been described in the above, where the argon gas and the nitrogen gas are supplied into chamber 21, the supplied gases are not limited thereto. For example, at least a part of the nitrogen gas may be replaced with ammonia gas, and at least a part of the argon gas may be replaced with hydrogen gas.

FIG. 4 illustrates a schematic configuration of another example of the DC magnetron sputtering apparatus used to stack aluminum-containing nitride intermediate layer 2 on the surface of substrate 1. The DC magnetron sputtering apparatus having the configuration shown in FIG. 4 is characterized in that Al target 26 is inclined with respect to the growth surface of substrate 1 to have a spacing between substrate 1 and Al target 26.

Al target 26 is inclined by an angle θ with respect to the direction normal to the growth surface of substrate 1. For the purpose of stacking aluminum-containing nitride intermediate layer 2 having excellent crystallinity, angle θ is preferably 10° or more and 45° or less, and more preferably 20° or more and 45° or less.

When, with Al target 26 inclined with respect to the growth surface of substrate 1 to have a spacing between substrate 1 and Al target 26, a voltage is applied between substrate 1 and Al target 26 by means of the DC-continuous scheme to stack aluminum-containing nitride intermediate layer 2 by using the DC magnetron sputtering method as described above, damage to the growth surface of substrate 1 due to the high-energy reactive species supplied to substrate 1 during stacking of aluminum-containing nitride intermediate layer 2 can be reduced. Therefore, there is a tendency to allow stacking of aluminum-containing nitride intermediate layer 2 having excellent crystallinity.

In addition, by inclining Al target 26 with respect to the growth surface of substrate 1, uniformity in thickness and crystallinity of aluminum-containing nitride intermediate layer 2 in the growth surface of substrate 1 is enhanced. Therefore, uniformity in characteristics of the nitride semiconductor element in the growth surface of substrate 1 tends to be enhanced, and the yield of the nitride semiconductor element tends to be enhanced.

In particular, as the diameter of the growth surface of substrate 1 is increased to 100 mm (4 inches), 125 mm (5 inches) and 150 mm (6 inches), the effect of the above enhancement of uniformity tends to become more pronounced.

In the DC magnetron sputtering apparatus having the configuration shown in FIG. 4 as well, shortest distance d between the center of the surface of Al target 26 and the growth surface of substrate 1 is preferably set to 100 mm or more and 250 mm or less, more preferably 120 mm or more and 210 mm or less, and still more preferably 150 mm or more and 180 mm or less. In the DC magnetron sputtering apparatus having the configuration shown in FIG. 4 as well, when above shortest distance d is set as described above, there is a tendency to allow stacking of aluminum-containing nitride intermediate layer 2 having more excellent crystallinity, due to the above reasons.

In addition, in the DC magnetron sputtering apparatus having the configuration shown in FIG. 4 as well, the volume ratio of the nitrogen gas (the ratio of nitrogen: %) to the gas supplied into chamber 21 is preferably 50% or more, more preferably 75% or more, and the most preferably 100% (only the nitrogen gas is supplied). In the DC magnetron sputtering apparatus having the configuration shown in FIG. 4 as well, when the ratio of nitrogen in the gas supplied into chamber 21 is set as described above, there is a tendency to allow stacking of aluminum-containing nitride intermediate layer 2 having more excellent crystallinity, due to the above reasons.

FIG. 5 illustrates a schematic configuration of still another example of the DC magnetron sputtering apparatus used to stack aluminum-containing nitride intermediate layer 2 on the surface of substrate 1. The DC magnetron sputtering apparatus having the configuration shown in FIG. 5 is characterized in that the DC magnetron sputtering apparatus includes a first cathode 28a having a first Al target 26a inclined with respect to the growth surface of substrate 1 to have a spacing between substrate 1 and first Al target 26a, and a second cathode 28b having a second Al target 26b inclined with respect to the growth surface of substrate 1 to have a spacing between substrate 1 and second Al target 26b.

First cathode 28a has first Al target 26a and a first magnet 27a supported by a first magnet support 29a. Second cathode 28b has second Al target 26b and a second magnet 27b supported by a second magnet support 29b.

First Al target 26a is inclined by an angle θ1 with respect to the direction normal to the growth surface of substrate 1. For the purpose of stacking aluminum-containing nitride intermediate layer 2 having excellent crystallinity, angle θ1 is preferably 10° or more and 45° or less, and more preferably 20° or more and 45° or less.

Second Al target 26b is inclined by an angle θ2 with respect to the direction normal to the growth surface of substrate 1. For the purpose of stacking aluminum-containing nitride intermediate layer 2 having excellent crystallinity, angle θ2 is preferably 10° or more and 45° or less, and more preferably 20° or more and 45° or less.

It is noted that for the purpose of stacking aluminum-containing nitride intermediate layer 2 having excellent crystallinity, either above angle θ1 or θ2 is preferably set to the above range, and more preferably, both θ1 and θ2 are set to the above range.

In FIG. 5, the DC magnetron sputtering apparatus in which two Al targets inclined with respect to the growth surface of the substrate are placed has been described. For the purpose of increasing the film formation speed of aluminum-containing nitride intermediate layer 2, however, the number of the Al target inclined with respect to the growth surface of the substrate can be increased to, for example, three, four, five, or the like.

In the DC magnetron sputtering apparatus having the configuration shown in FIG. 5, a shortest distance d1 between a center of a surface of first Al target 26a and the growth surface of substrate 1 is preferably set to 100 mm or more and 250 mm or less, more preferably 120 mm or more and 210 mm or less, and still more preferably 150 mm or more and 180 mm or less. In the DC magnetron sputtering apparatus having the configuration shown in FIG. 5, when above shortest distance d1 is set as described above, there is a tendency to allow stacking of aluminum-containing nitride intermediate layer 2 having more excellent crystallinity, due to the above reasons.

In addition, in the DC magnetron sputtering apparatus having the configuration shown in FIG. 5, a shortest distance d2 between a center of a surface of second Al target 26b and the growth surface of substrate 1 is preferably set to 100 mm or more and 250 mm or less, more preferably 120 mm or more and 210 mm or less, and still more preferably 150 mm or more and 180 mm or less. In the DC magnetron sputtering apparatus having the configuration shown in FIG. 5, when above shortest distance d2 is set as described above, there is a tendency to allow stacking of aluminum-containing nitride intermediate layer 2 having more excellent crystallinity, due to the above reasons.

It is noted that for the purpose of stacking aluminum-containing nitride intermediate layer 2 having excellent crystallinity, either above shortest distance d1 or d2 is preferably set to the above range, and more preferably, both d1 and d2 are set to the above range.

In addition, in the DC magnetron sputtering apparatus having the configuration shown in FIG. 5 as well, the volume ratio of the nitrogen gas (the ratio of nitrogen: %) to the gas supplied into chamber 21 is preferably 50% or more, more preferably 75% or more, and the most preferably 100% (only the nitrogen gas is supplied). In the DC magnetron sputtering apparatus having the configuration shown in FIG. 5 as well, when the ratio of nitrogen in the gas supplied into chamber 21 is set as described above, there is a tendency to allow stacking of aluminum-containing nitride intermediate layer 2 having more excellent crystallinity, due to the above reasons.

As described above, in the present embodiment, at least one of the following conditions (a) to (c) is employed during stacking of the aluminum-containing nitride intermediate layer by using the DC magnetron sputtering method in which a voltage is applied between the substrate and the target by means of the DC-continuous scheme. As a result, the aluminum-containing nitride intermediate layer having excellent crystallinity and formed of the aggregate of columnar crystals each having the array of crystal grains that extend in the direction normal to the growth surface of the substrate is stacked on the growth surface of the substrate. Then, the nitride layer is grown on the surface of such aluminum-containing nitride intermediate layer having excellent crystallinity. As a result, the nitride layer having low dislocation density and excellent crystallinity can be obtained with good reproducibility, and in turn, the nitride semiconductor element having excellent characteristics can be fabricated with good reproducibility.

(a) The shortest distance between the center of the surface of the target and the growth surface of the substrate is set to 100 mm or more and 250 mm or less, more preferably 120 mm or more and 210 mm or less, and still more preferably 150 mm or more and 180 mm or less.
(b) The volume ratio of the nitrogen gas (the ratio of nitrogen: %) to the gas supplied to the DC magnetron sputtering apparatus is set to 50% or more, more preferably 75% or more, and still more preferably 100% (only the nitrogen gas is supplied).
(c) The target is inclined with respect to the growth surface of the substrate.

It is noted that any one of the above conditions (a) to (c) may only be employed in order to stack the aluminum-containing nitride intermediate layer having excellent crystallinity on the growth surface of the substrate. In order to obtain the aluminum-containing nitride intermediate layer having more excellent crystallinity, any two of the above conditions (a) to (c) are preferably employed, and the most preferably, all of the above conditions (a) to (c) are employed.

In addition, aluminum-containing nitride intermediate layer 2 preferably covers the growth surface of substrate 1 without any gap. When the growth surface of substrate 1 is exposed at aluminum-containing nitride intermediate layer 2, a hillock or a pit may occur at the nitride layer formed on aluminum-containing nitride intermediate layer 2.

It is noted that aluminum-containing nitride intermediate layer 2 can be provided by stacking, for example, a nitride semiconductor layer formed of a nitride semiconductor represented by an expression of Alₓ₀Ga_{yo}N (0≦x0≦1, 0≦y0≦1, x0+y0≠0). In particular, a nitride semiconductor layer formed of a nitride semiconductor (aluminum nitride) represented by an expression of AlN is preferably stacked, for the purpose of obtaining aluminum-containing nitride intermediate layer 2 having excellent crystallinity and formed of the aggregate of columnar crystals each having the array of crystal grains that extend in the direction normal to the growth surface of substrate 1.

In addition, aluminum-containing nitride intermediate layer 2 stacked on the growth surface of substrate 1 preferably has a thickness of 5 nm or more and 100 nm or less. When aluminum-containing nitride intermediate layer 2 has a thickness of less than 5 nm, aluminum-containing nitride intermediate layer 2 may not sufficiently function as the buffer layer. When the thickness of aluminum-containing nitride intermediate layer 2 exceeds 100 nm, the function as the buffer layer is never enhanced and the formation time period of aluminum-containing nitride intermediate layer 2 may be prolonged. For the purpose of causing aluminum-containing nitride intermediate layer 2 to function as the buffer layer uniformly within the surface, the thickness of aluminum-containing nitride intermediate layer 2 is more preferably set to 10 nm or more and 50 nm or less.

Furthermore, the temperature of substrate 1 during stacking of aluminum-containing nitride intermediate layer 2 is preferably 300° C. or more and 1000° C. or less. When the temperature of substrate 1 during stacking of aluminum-containing nitride intermediate layer 2 is less than 300° C., aluminum-containing nitride intermediate layer 2 cannot cover the entire growth surface of substrate 1 and a part of the growth surface of substrate 1 may be exposed at aluminum-containing nitride intermediate layer 2. When the temperature of substrate 1 during stacking of aluminum-containing nitride intermediate layer 2 exceeds 1000° C., migration of the material in the growth surface of substrate 1 becomes too active, and aluminum-containing nitride intermediate layer 2 closer to a single-crystal film than the aggregate of columnar crystals is formed. As a result, the function of aluminum-containing nitride intermediate layer 2 as the buffer layer may be lowered.

Moreover, the pressure within chamber 21 during stacking of aluminum-containing nitride intermediate layer 2 is preferably 0.2 Pa or more. When the pressure within chamber 21 during stacking of aluminum-containing nitride intermediate layer 2 is less than 0.2 Pa, the amount of nitrogen within chamber 21 decreases, and aluminum sputtered from Al target 26 may not form into nitride and may attach onto the growth surface of substrate 1. The upper limit of the pressure within chamber 21 during stacking of aluminum-containing nitride intermediate layer 2 is not particularly limited. Any pressure is possible as long as the pressure is at a level that allows generation of plasma within chamber 21.

It is desirable that impurities should not be present within chamber 21 during stacking of aluminum-containing nitride intermediate layer 2. Therefore, for the purpose of obtaining aluminum-containing nitride intermediate layer 2 having excellent crystallinity, the pressure within chamber 21 immediately before sputtering is preferably 1×10⁻³ Pa or less.

In addition, the formation speed of aluminum-containing nitride intermediate layer 2 is preferably 0.01 nm/sec or more and 1 nm/sec or less. When the formation speed of aluminum-containing nitride intermediate layer 2 is less than 0.01 nm/sec, there is a possibility that aluminum-containing nitride intermediate layer 2 does not spread out uniformly but grows in the form of an island on the growth surface of substrate 1 and aluminum-containing nitride intermediate layer 2 cannot cover the growth surface of substrate 1 uniformly, and the growth surface of substrate 1 is exposed at aluminum-containing nitride intermediate layer 2. When the formation speed of aluminum-containing nitride intermediate layer 2 exceeds 1 nm/sec, there is a possibility that aluminum-containing nitride intermediate layer 2 becomes amorphous and the nitride layer having low dislocation density and excellent crystallinity cannot be grown on aluminum-containing nitride intermediate layer 2.

The growth surface of substrate 1 before aluminum-containing nitride intermediate layer 2 is stacked may be subjected to pretreatment. The pretreatment of the growth surface of substrate 1 includes, as an example, a treatment of hydrogen terminating the growth surface of substrate 1 by RCA cleaning similar to cleaning commonly performed to a silicon substrate. As a result, there is a tendency to allow stacking of aluminum-containing nitride intermediate layer 2 having excellent crystallinity on the growth surface of substrate 1 with good reproducibility.

The pretreatment of the growth surface of substrate 1 includes, as another example, a treatment of exposing the growth surface of substrate 1 to plasma of the nitrogen gas. As a result, there is a tendency to allow removal of foreign substances such as organic substances and oxides attached to the growth surface of substrate 1 and improvement in the condition of the growth surface of substrate 1. In particular, when substrate 1 is the sapphire substrate, exposure of the growth surface of substrate 1 to plasma of the nitrogen gas tends to cause nitriding of the growth surface of substrate 1 and facilitate uniform formation, in the growth surface of substrate 1, of aluminum-containing nitride intermediate layer 2 stacked on the growth surface of substrate 1.

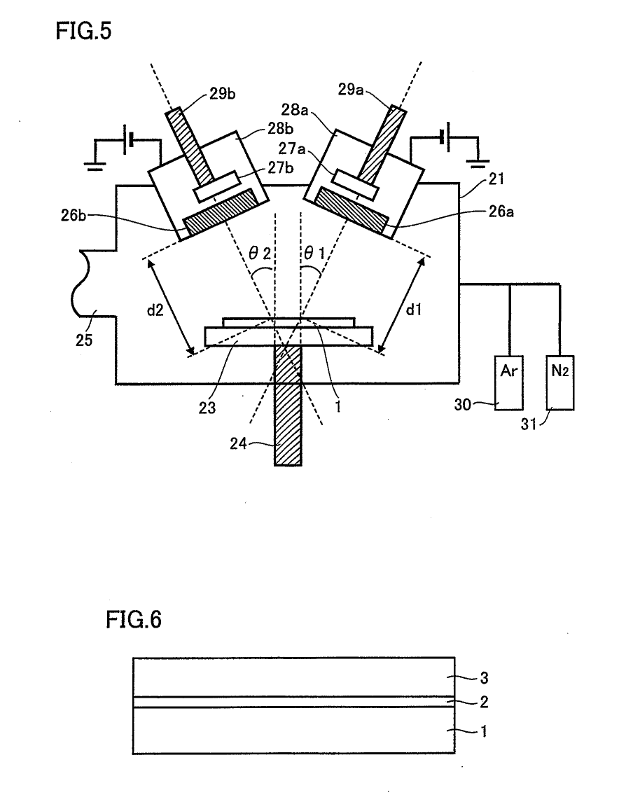

Next, as shown in a schematic cross-sectional view in FIG. 6, nitride semiconductor underlying layer 3 is stacked on the surface of aluminum-containing nitride intermediate layer 2 by using an MOCVD (Metal Organic Chemical Vapor Deposition) method.

Nitride semiconductor underlying layer 3 can be provided by stacking, for example, a nitride semiconductor layer formed of a III group nitride semiconductor represented by an expression of Alₓ₁Ga_{y1}In_{z1}N (0≦x1≦1, 0≦y1≦1, 0≦z1≦1, x1+y1+z1≠0). In order not to take over crystal defects such as dislocation in aluminum-containing nitride intermediate layer 2 formed of the aggregate of columnar crystals, nitride semiconductor underlying layer 3 preferably includes Ga as a III group element. In order not to take over dislocation in aluminum-containing nitride intermediate layer 2, it is necessary to loop the dislocation near an interface between aluminum-containing nitride intermediate layer 2 and nitride semiconductor underlying layer 3. When nitride semiconductor underlying layer 3 is formed of the III group nitride semiconductor including Ga, however, a dislocation loop readily occurs. Accordingly, the use of nitride semiconductor underlying layer 3 formed of the III group nitride semiconductor including Ga allows looping and confining of the dislocation near the interface between aluminum-containing nitride intermediate layer 2 and nitride semiconductor underlying layer 3, and suppression of takeover of the dislocation from aluminum-containing nitride intermediate layer 2 to nitride semiconductor underlying layer 3. In particular, when nitride semiconductor underlying layer 3 is formed of a III group nitride semiconductor represented by an expression of Alₓ₁Ga_{y1}N (0<x1<1, 0<y1<1), in particular GaN, the dislocation can be looped and confined near the interface between aluminum-containing nitride intermediate layer 2 and nitride semiconductor underlying layer 3. Therefore, nitride semiconductor underlying layer 3 having low dislocation density and excellent crystallinity tends to be obtained.

The surface of aluminum-containing nitride intermediate layer 2 immediately before nitride semiconductor underlying layer 3 is stacked may be subjected to heat treatment. This heat treatment tends to allow cleaning of the surface and enhancement of the crystallinity of aluminum-containing nitride intermediate layer 2. This heat treatment can be performed within, for example, an MOCVD apparatus in which the MOCVD method is used, and the hydrogen gas and/or the nitrogen gas, for example, can be used as the atmosphere gas in heat treatment. In addition, in order to prevent decomposition of aluminum-containing nitride intermediate layer 2 during the above heat treatment, the ammonia gas may be mixed with the atmosphere gas in heat treatment. Furthermore, the above heat treatment can be performed at a temperature of, for example, 900° C. or more and 1250° C. or less for a time period of, for example, one minute or more and 60 minutes or less.

It is noted that nitride semiconductor underlying layer 3 may be doped with an n-type dopant in the range of 1×10¹⁷ cm⁻³ or more and 1×10¹⁹ cm⁻³ or less. For the purpose of maintaining the excellent crystallinity, however, nitride semiconductor underlying layer 3 is preferably undoped. It is noted that silicon, germanium, tin and the like, for example, can be used as the n-type dopant, and in particular, the use of silicon and/or germanium is preferable.

In addition, the temperature of substrate 1 during stacking of nitride semiconductor underlying layer 3 is preferably 800° C. or more and 1250° C. or less, and more preferably 1000° C. or more and 1250° C. or less. When the temperature of substrate 1 during stacking of nitride semiconductor underlying layer 3 is 800° C. or more and 1250° C. or less, in particular 1000° C. or more and 1250° C. or less, there is a tendency to allow growth of nitride semiconductor underlying layer 3 having excellent crystallinity.

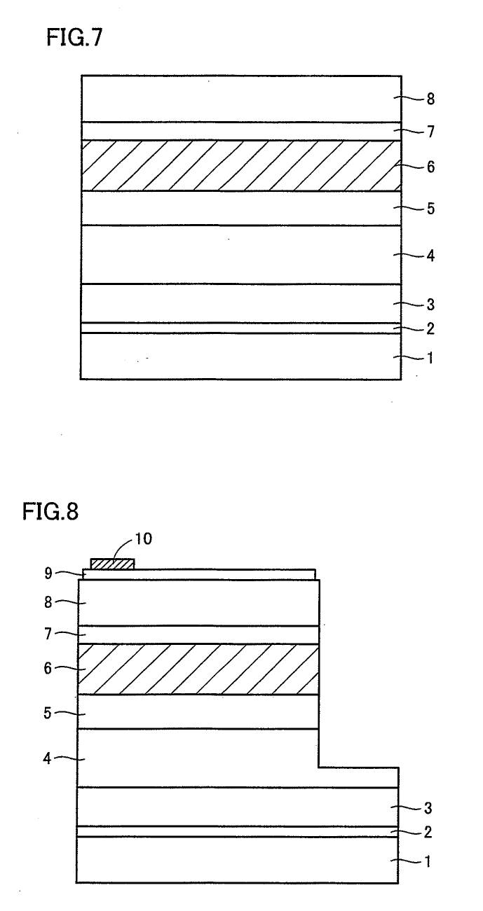

Next, as shown in a schematic cross-sectional view in FIG. 7, n-type nitride semiconductor contact layer 4, n-type nitride semiconductor clad layer 5, nitride semiconductor active layer 6, p-type nitride semiconductor clad layer 7, and p-type nitride semiconductor contact layer 8 are stacked in this order on the surface of nitride semiconductor underlying layer 3 by using the MOCVD method. As a result, a stacked body is formed.

N-type nitride semiconductor contact layer 4 can be provided by stacking, for example, a layer and the like obtained by doping, with the n-type dopant, a nitride semiconductor layer formed of a III group nitride semiconductor represented by an expression of Alₓ₂Ga_{y2}In_{z2}N (0≦x2≦1, 0≦y2≦1, 0≦z2≦1, x2+y2+z2≠0).

In particular, n-type nitride semiconductor contact layer 4 is preferably a nitride semiconductor layer obtained by doping, with silicon serving as the n-type dopant, a III group nitride semiconductor represented by an expression of Alₓ₂Ga₁₋ₓ₂N (0≦x2≦1, preferably 0≦x2≦0.5, and more preferably 0≦x2≦0.1).

In addition, for the purpose of maintaining excellent ohmic contact with n-side electrode 11 as well as suppressing occurrence of cracks and maintaining the excellent crystallinity in n-type nitride semiconductor contact layer 4, the doping concentration of the n-type dopant in n-type nitride semiconductor contact layer 4 is preferably within the range of 5×10¹⁷ cm⁻³ or more and 5×10¹⁹ cm⁻³ or less.

Furthermore, for the purpose of maintaining the excellent crystallinity of nitride semiconductor underlying layer 3 and n-type nitride semiconductor contact layer 4, the total thickness of nitride semiconductor underlying layer 3 and n-type nitride semiconductor contact layer 4 is preferably 4 μm or more and 20 μm or less, more preferably 4 μm or more and 15 μm or less, and still more preferably 6 μm or more and 15 μm or less. When the total thickness of nitride semiconductor underlying layer 3 and n-type nitride semiconductor contact layer 4 is less than 4 μm, the crystallinity of these layers may worsen or a pit may occur on the surface of these layers. On the other hand, when the total thickness of nitride semiconductor underlying layer 3 and n-type nitride semiconductor contact layer 4 exceeds 15 μm, warpage of substrate 1 may increase and the yield of the element may be reduced. When the total thickness of nitride semiconductor underlying layer 3 and n-type nitride semiconductor contact layer 4 is 4 μm or more and 15 μm or less, in particular 6 μm or more and 15 μm or less, there is a tendency to allow achievement of the excellent crystallinity of these layers and effective prevention of the reduction in yield of the element due to the increased warpage of substrate 1. It is noted that the upper limit of the thickness of n-type nitride semiconductor contact layer 4 in the total thickness of these layers is not particularly limited.

N-type nitride semiconductor clad layer 5 can be provided by stacking, for example, a layer and the like obtained by doping, with the n-type dopant, a nitride semiconductor layer formed of a III group nitride semiconductor represented by an expression of Alₓ₃Ga_{y3}In_{z3}N (0≦x3≦1, 0≦y3≦1, 0≦z3≦1, x3+y3+z3≠0). N-type nitride semiconductor clad layer 5 may have a superlattice structure or a structure in which a plurality of nitride semiconductor layers each formed of the III group nitride semiconductor are joined in a heterojunction manner. Although the thickness of n-type nitride semiconductor clad layer 5 is not particularly limited, the thickness of n-type nitride semiconductor clad layer 5 is preferably 0.005 μm or more and 0.5 μm or less, and more preferably 0.005 μm or more and 0.1 μm or less. For the purpose of maintaining the excellent crystallinity and reducing the operation voltage of the element, the doping concentration of the n-type dopant in n-type nitride semiconductor clad layer 5 is preferably 1×10¹⁷ cm⁻³ or more and 1×10²⁰ cm⁻³ or less, and more preferably 1×10¹⁸ cm⁻³ or more and 1×10¹⁹ cm⁻³ or less.

When nitride semiconductor active layer 6 has, for example, a single quantum well (SQW) structure, nitride semiconductor active layer 6 can be provided by, for example, a layer in which a nitride semiconductor layer formed of a III group nitride semiconductor represented by an expression of Ga_{1-z4}In_{z4}N (0<z4<0.4) is configured as a quantum well layer. Although the thickness of nitride semiconductor active layer 6 is not particularly limited, the thickness of nitride semiconductor active layer 6 is preferably 1 nm or more and 10 nm or less, and more preferably 1 nm or more and 6 nm or less, for the purpose of enhancing the light emission output.

When nitride semiconductor active layer 6 has, for example, the single quantum well (SQW) structure in which the nitride semiconductor layer formed of the III group nitride semiconductor represented by the expression of Ga_{1-z4}In_{z4}N (0<z4<0.4) is configured as the quantum well layer, the In composition and thickness of nitride semiconductor active layer 6 are controlled to achieve a desired light emission wavelength. However, when the temperature of substrate 1 during formation of nitride semiconductor active layer 6 is low, the crystallinity may worsen. On the other hand, when the temperature of substrate 1 during formation of nitride semiconductor active layer 6 is high, sublimation of InN may become pronounced, efficiency of taking In into the solid phase may be reduced, and the In composition may vary. Therefore, the temperature of substrate 1 during formation of nitride semiconductor active layer 6 having the single quantum well (SQW) structure in which the nitride semiconductor layer formed of the III group nitride semiconductor represented by the expression of Ga_{1-z4}In_{z4}N (0<z4<0.4) is configured as the well layer is preferably 700° C. or more and 900° C. or less, and more preferably 750° C. or more and 850° C. or less.

In addition, nitride semiconductor active layer 6 can also be provided by, for example, a layer having a multiple quantum well (MQW) structure in which the nitride semiconductor layer formed of the III group nitride semiconductor represented by the expression of Ga_{1-z4}In_{z4}N (0<z4<0.4) is configured as the quantum well layer, and a nitride semiconductor layer formed of a nitride semiconductor represented by an expression of Alₓ₅Ga_{y5}In_{z5}N (0≦x5≦1, 0≦y5≦1, 0≦z5≦1, x5+y5+z5≠0) and having a bandgap larger than a bandgap of that well layer is configured as a quantum barrier layer, and the quantum well layer and the quantum barrier layer are alternately stacked one by one. It is noted that the above quantum well layer and/or the quantum barrier layer may be doped with the n-type or p-type dopant.

P-type nitride semiconductor clad layer 7 can be provided by stacking, for example, a layer and the like obtained by doping, with the p-type dopant, a nitride semiconductor layer formed of a III group nitride semiconductor represented by an expression of Alₓ₆Ga_{y6}In_{z6}N (0≦x6≦1, 0≦y6≦1, 0≦z6≦1, x6+y6+z6≠0). In particular, it is preferable to stack the layer obtained by doping, with the p-type dopant, a nitride semiconductor layer formed of a III group nitride semiconductor represented by an expression of Alₓ₆Ga₁₋ₓ₆N (0<x6≦0.4, and preferably 0.1≦x6≦0.3). It is noted that magnesium and the like, for example, can be used as the p-type dopant.

For the purpose of confining light in nitride semiconductor active layer 6, p-type nitride semiconductor clad layer 7 preferably has a bandgap larger than that of nitride semiconductor active layer 6. Although the thickness of p-type nitride semiconductor clad layer 7 is not particularly limited, the thickness of p-type nitride semiconductor clad layer 7 is preferably 0.01 μm or more and 0.4 μm or less, and more preferably 0.02 μm or more and 0.1 μm or less. For the purpose of obtaining p-type nitride semiconductor clad layer 7 having excellent crystallinity, the doping concentration of the p-type dopant in p-type nitride semiconductor clad layer 7 is preferably 1×10¹⁸ cm⁻³ or more and 1×10²¹ cm⁻³ or less, and more preferably 1×10¹⁹ cm⁻³ or more and 1×10²⁰ cm⁻³ or less.

P-type nitride semiconductor contact layer 8 can be provided by stacking, for example, a layer and the like obtained by doping, with the p-type dopant, a nitride semiconductor layer formed of a III group nitride semiconductor represented by an expression of Alₓ₇Ga_{y7}In_{z7}N (0≦x7≦1, 0≦y7≦1, 0≦z7≦1, x7+y7+z7≠0). In particular, for the purpose of maintaining the excellent crystallinity and obtaining excellent ohmic contact, the use of a layer obtained by doping a GaN layer with the p-type dopant is preferable.

For the purpose of maintaining excellent ohmic contact as well as suppressing occurrence of cracks and maintaining the excellent crystallinity in p-type nitride semiconductor contact layer 8, the doping concentration of the p-type dopant in p-type nitride semiconductor contact layer 8 is preferably within the range of 1×10¹⁸ cm⁻³ or more and 1×10²¹ cm⁻³ or less, and more preferably within the range of 5×10¹⁹ cm⁻³ or more and 5×10²⁰ cm⁻³ or less. Although the thickness of p-type nitride semiconductor contact layer 8 is not particularly limited, the thickness of p-type nitride semiconductor contact layer 8 is preferably 0.01 μm or more and 0.5 μm or less, and more preferably 0.05 μm or more and 0.2 μm or less, for the purpose of enhancing the light emission output of nitride semiconductor light-emitting diode element 100.

When above n-type nitride semiconductor contact layer 4, n-type nitride semiconductor clad layer 5, nitride semiconductor active layer 6, p-type nitride semiconductor clad layer 7, and p-type nitride semiconductor contact layer 8 are formed of the III group nitride semiconductor, respectively, these layers are, for example, stacked by using the MOCVD method as follows.

In other words, these layers can be stacked by supplying organic metal material gas having at least one III group element selected from the group consisting of, for example, trimethyl gallium (TMG), trimethyl aluminum (TMA) and trimethyl indium (TMI), as well as nitrogen material gas such as ammonia, for example, into a reactor of the MOCVD apparatus, and thermally decomposing and reacting these.

When doping with silicon serving as the n-type dopant is performed, doping with silicon can be achieved by supplying, for example, silane (SiH₄) as doping gas into the reactor of the MOCVD apparatus, in addition to the above material gases.

When doping with magnesium serving as the p-type dopant is performed, doping with magnesium can be achieved by supplying, for example, bis(cyclopentadienyl)magnesium (CP₂Mg) as doping gas into the reactor of the MOCVD apparatus, in addition to the above material gases.

Next, as shown in a schematic cross-sectional view in FIG. 8, translucent electrode layer 9 made of, for example, ITO (Indium Tin Oxide) is formed on the surface of p-type nitride semiconductor contact layer 8, and then, p-side electrode 10 is formed on the surface of translucent electrode layer 9. Thereafter, a part of the stacked body having p-side electrode 10 formed is removed by etching to expose a part of the surface of n-type nitride semiconductor contact layer 4.

Thereafter, as shown in FIG. 1, n-side electrode 11 is formed on the exposed surface of n-type nitride semiconductor contact layer 4. As a result, nitride semiconductor light-emitting diode element 100 of the first embodiment can be fabricated.

In nitride semiconductor light-emitting diode element 100 of the first embodiment fabricated in the foregoing manner, nitride semiconductor underlying layer 3, n-type nitride semiconductor contact layer 4, n-type nitride semiconductor clad layer 5, nitride semiconductor active layer 6, p-type nitride semiconductor clad layer 7, and p-type nitride semiconductor contact layer 8 are stacked in this order on the surface of aluminum-containing nitride intermediate layer 2 having excellent crystallinity and formed of the aggregate of columnar crystals each having the array of crystal grains that extend in the direction (perpendicular direction) normal to the growth surface of substrate 1, as described above. Therefore, these layers stacked on the surface of aluminum-containing nitride intermediate layer 2 have low dislocation density and excellent crystallinity. Accordingly, nitride semiconductor light-emitting diode element 100 of the first embodiment formed of such layers having excellent crystallinity achieves low operation voltage and high light emission output.

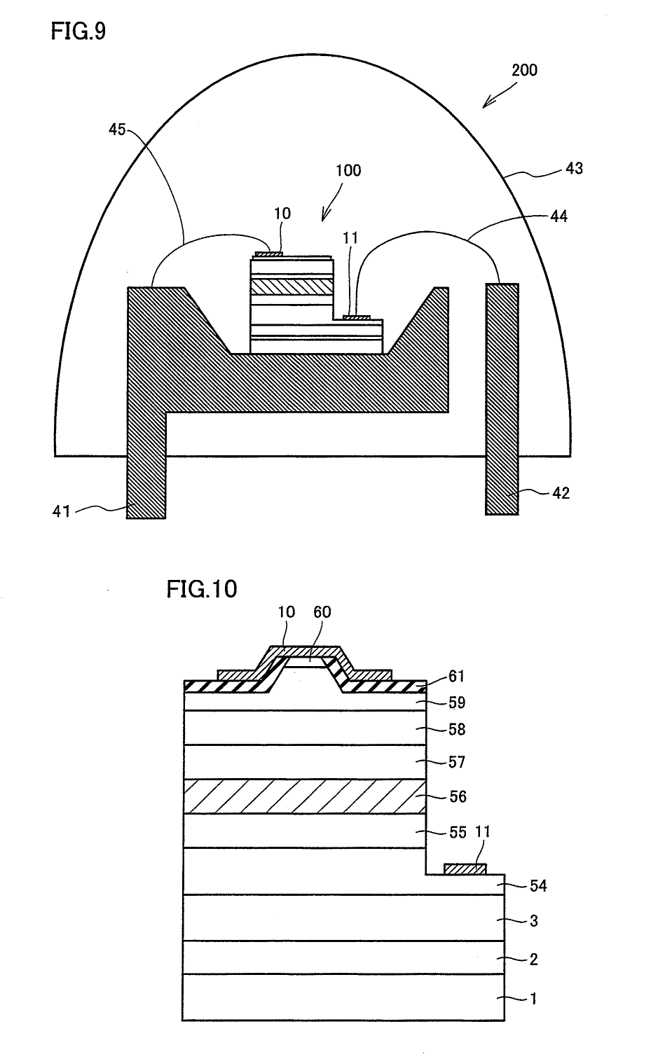

FIG. 9 shows a schematic cross-sectional view of an example of a light-emitting apparatus in which nitride semiconductor light-emitting diode element 100 of the first embodiment is used. A light-emitting apparatus 200 having a configuration shown in FIG. 9 is configured such that nitride semiconductor light-emitting diode element 100 of the first embodiment is placed on a first lead frame 41. P-side electrode 10 of nitride semiconductor light-emitting diode element 100 is electrically connected to first lead frame 41 by a first wire 45, and n-side electrode 11 of nitride semiconductor light-emitting diode element 100 is electrically connected to a second lead frame 42 by a second wire 44. Furthermore, nitride semiconductor light-emitting diode element 100 is molded by a transparent mold resin 43, thereby achieving light-emitting apparatus 200 in the shape of a bombshell.

Since nitride semiconductor light-emitting diode element 100 of the first embodiment is used, the light-emitting apparatus having the configuration shown in FIG. 9 can achieve low operation voltage and high light emission output.

### Second Embodiment

The present embodiment is characterized in that a nitride semiconductor laser element, not the nitride semiconductor light-emitting diode element, is fabricated.

FIG. 10 shows a schematic cross-sectional view of a nitride semiconductor laser element of a second embodiment that is another example of the nitride semiconductor element of the present invention.

In the nitride semiconductor laser element of the second embodiment, aluminum-containing nitride intermediate layer 2, nitride semiconductor underlying layer 3, an n-type nitride semiconductor clad layer 54, an n-type nitride semiconductor light guide layer 55, a nitride semiconductor active layer 56, a nitride semiconductor protection layer 57, a p-type nitride semiconductor light guide layer 58, a p-type nitride semiconductor clad layer 59, and a p-type nitride semiconductor contact layer 60 are stacked in this order on the surface of substrate 1. An insulating film 61 is formed to cover an upper surface of p-type nitride semiconductor clad layer 59 and a side surface of p-type nitride semiconductor contact layer 60, respectively. In addition, n-side electrode 11 is placed to be in contact with an exposed surface of n-type nitride semiconductor clad layer 54, and p-side electrode 10 is placed to be in contact with an exposed surface of p-type nitride semiconductor contact layer 60.

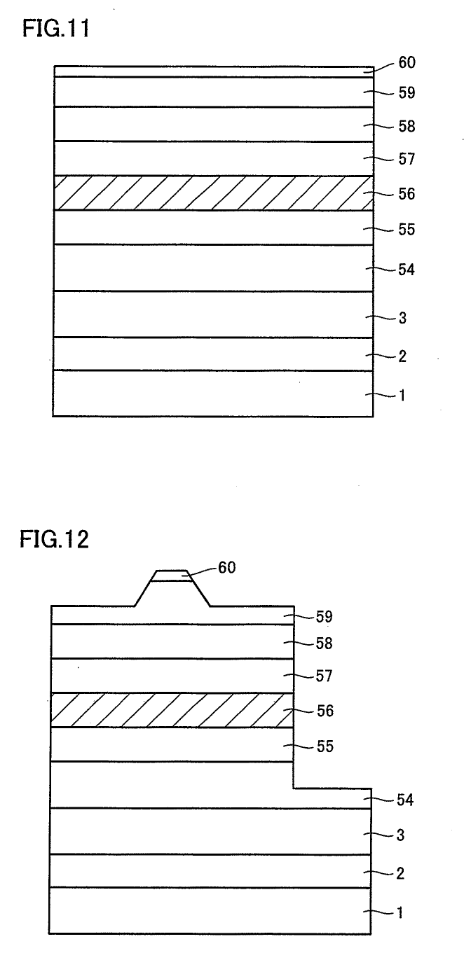

An example of a method for manufacturing the nitride semiconductor laser element of the second embodiment will be described hereinafter. First, as shown in a schematic cross-sectional view in FIG. 11, aluminum-containing nitride intermediate layer 2 and nitride semiconductor underlying layer 3 are stacked in this order on the growth surface of substrate 1 as in the first embodiment, and then, n-type nitride semiconductor clad layer 54, n-type nitride semiconductor light guide layer 55, nitride semiconductor active layer 56, nitride semiconductor protection layer 57, p-type nitride semiconductor light guide layer 58, p-type nitride semiconductor clad layer 59, and p-type nitride semiconductor contact layer 60 are stacked in this order by using the MOCVD method. As a result, a stacked body is formed.

N-type nitride semiconductor clad layer 54 can be provided by stacking, for example, a layer and the like obtained by doping, with the n-type dopant, a nitride semiconductor layer formed of a III group nitride semiconductor represented by an expression of Alₓ₈Ga_{y8}In_{z8}N (0≦x8≦1, 0≦y8≦1, 0≦z8≦1, x8+y8+z8≠0).

N-type nitride semiconductor light guide layer 55 can be provided by stacking, for example, a layer and the like obtained by doping, with the n-type dopant, a nitride semiconductor layer formed of a III group nitride semiconductor represented by an expression of Alₓ₉Ga_{y9}In_{z9}N (0≦x9≦1, 0≦y9≦1, 0≦z9≦1, x9+y9+z9≠0).

Nitride semiconductor active layer 56 can be provided by stacking, for example, a layer and the like obtained by alternately stacking one by one a nitride semiconductor layer formed of a III group nitride semiconductor represented by an expression of Alₓ₁₀Ga_{y10}In_{z10}N (0≦x10≦1, 0≦y10≦1, 0≦z10≦1, x10+y10+z10≠0) and a nitride semiconductor layer formed of a III group nitride semiconductor represented by an expression of Alₓ₁₁Ga_{y11}In_{z11}N (0≦x11≦1, 0≦y11≦1, 0≦z11≦1, x11+y11+z11≠0), each of the nitride semiconductor layers having different composition.

Nitride semiconductor protection layer 57 can be provided by stacking, for example, a nitride semiconductor layer formed of a III group nitride semiconductor represented by an expression of Alₓ₁₂Ga_{y12}In_{z12}N (0≦x12≦1, 0≦y12≦1, 0≦z12≦1, x12+y12+z12≠0).

P-type nitride semiconductor light guide layer 58 can be provided by stacking, for example, a layer and the like obtained by doping, with the p-type dopant, a nitride semiconductor layer formed of a III group nitride semiconductor represented by an expression of Alₓ₁₃Ga_{y13}In_{z13}N (0≦x13≦1, 0≦y13≦1, 0≦z13≦1, x13+y13+z13≠0).

P-type nitride semiconductor clad layer 59 can be provided by stacking, for example, a layer and the like obtained by doping, with the p-type dopant, a nitride semiconductor layer formed of a III group nitride semiconductor represented by an expression of Alₓ₁₄Ga_{y14}In_{z14}N (0≦x14≦1, 0≦y14≦1, 0≦z14≦1, x14+y14+z14≠0).

P-type nitride semiconductor contact layer 60 can be provided by stacking, for example, a layer and the like obtained by doping, with the p-type dopant, a nitride semiconductor layer formed of a III group nitride semiconductor represented by an expression of Alₓ₁₅Ga_{y15}In_{z15}N (0≦x15≦1, 0≦y15≦1, 0≦z15≦1, x15+y15+z15≠0).

Next, as shown in a schematic cross-sectional view in FIG. 12, a part of each of p-type nitride semiconductor clad layer 59 and p-type nitride semiconductor contact layer 60 of the stacked body shown in FIG. 11 is removed by etching to expose a part of a surface of p-type nitride semiconductor clad layer 59. In addition, a part of the stacked body shown in FIG. 11 is removed by etching to expose a part of a surface of n-type nitride semiconductor clad layer 54.

Thereafter, as shown in FIG. 10, insulating film 61 made of, for example, silicon oxide is formed to expose a surface of p-type nitride semiconductor contact layer 60 and to cover the exposed surface of p-type nitride semiconductor clad layer 59. Then, n-side electrode 11 is formed on the exposed surface of n-type nitride semiconductor clad layer 54, and p-side electrode 10 that is in contact with p-type nitride semiconductor contact layer 60 is formed on insulating film 61. As a result, the nitride semiconductor laser element of the second embodiment can be fabricated.

In the nitride semiconductor laser element of the second embodiment as well, at least one of the above conditions (a) to (c) is employed during stacking of aluminum-containing nitride intermediate layer 2 by using the DC magnetron sputtering method in which a voltage is applied between the substrate and the target by means of the DC-continuous scheme, as in the first embodiment. As a result, aluminum-containing nitride intermediate layer 2 having excellent crystallinity and formed of the aggregate of columnar crystals each having the array of crystal grains that extend in the direction normal to the growth surface of substrate 1 is stacked on the growth surface of substrate 1. Then, nitride semiconductor underlying layer 3, n-type nitride semiconductor clad layer 54, n-type nitride semiconductor light guide layer 55, nitride semiconductor active layer 56, nitride semiconductor protection layer 57, p-type nitride semiconductor light guide layer 58, p-type nitride semiconductor clad layer 59, and p-type nitride semiconductor contact layer 60 are grown in this order on the surface of such aluminum-containing nitride intermediate layer 2 having excellent crystallinity.

Accordingly, in the nitride semiconductor laser element of the second embodiment as well, the respective layers stacked on the surface of aluminum-containing nitride intermediate layer 2 can have low dislocation density and high crystallinity. Therefore, the nitride semiconductor laser element of the second embodiment can achieve low operation voltage and high light emission output.

### Third Embodiment

The present embodiment is characterized in that a nitride semiconductor transistor element that is an example of an electronic device, not a light-emitting device such as the nitride semiconductor light-emitting diode element and the nitride semiconductor laser element, is fabricated.

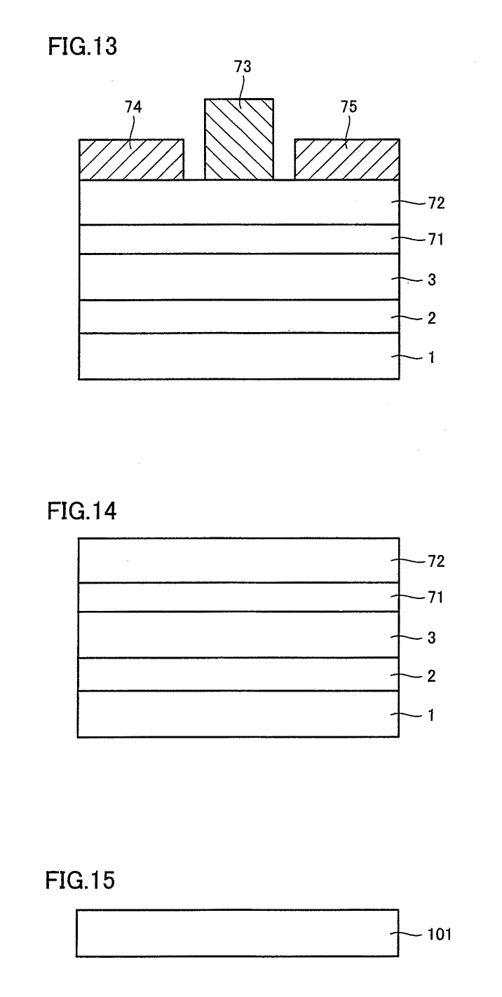

FIG. 13 shows a schematic cross-sectional view of a nitride semiconductor transistor element of a third embodiment that is another example of the nitride semiconductor element of the present invention.

In the nitride semiconductor transistor element of the third embodiment, aluminum-containing nitride intermediate layer 2 and nitride semiconductor underlying layer 3 are stacked in this order on the growth surface of substrate 1. A nitride semiconductor electron transit layer 71 made of undoped GaN and the like is stacked on the surface of nitride semiconductor underlying layer 3, and an n-type nitride semiconductor electron supply layer 72 made of n-type AlGaN and the like is stacked on a surface of nitride semiconductor electron transit layer 71. A source electrode 74, a drain electrode 75 and a gate electrode 73 are formed on a surface of n-type nitride semiconductor electron supply layer 72.

An example of a method for manufacturing the nitride semiconductor transistor element of the third embodiment will be described hereinafter. First, aluminum-containing nitride intermediate layer 2 and nitride semiconductor underlying layer 3 are stacked in this order on the growth surface of substrate 1 as in the first embodiment.

Next, as shown in a schematic cross-sectional view in FIG. 14, nitride semiconductor electron transit layer 71 is stacked on the surface of nitride semiconductor underlying layer 3 and n-type nitride semiconductor electron supply layer 72 is stacked on the surface of nitride semiconductor electron transit layer 71 by using the MOCVD method.

Thereafter, as shown in FIG. 13, source electrode 74, drain electrode 75 and gate electrode 73 are formed on the surface of n-type nitride semiconductor electron supply layer 72, respectively. As a result, the nitride semiconductor transistor element of the third embodiment can be fabricated.

In the nitride semiconductor transistor element of the third embodiment as well, at least one of the above conditions (a) to (c) is employed during stacking of aluminum-containing nitride intermediate layer 2 by using the DC magnetron sputtering method in which a voltage is applied between the substrate and the target by means of the DC-continuous scheme, as in the first embodiment. As a result, aluminum-containing nitride intermediate layer 2 having excellent crystallinity and formed of the aggregate of columnar crystals each having the array of crystal grains that extend in the direction normal to the growth surface of substrate 1 is stacked on the growth surface of substrate 1. Then, nitride semiconductor underlying layer 3, nitride semiconductor electron transit layer 71 and n-type nitride semiconductor electron supply layer 72 are grown in this order on the surface of such aluminum-containing nitride intermediate layer 2 having excellent crystallinity.

Accordingly, in the nitride semiconductor transistor element of the third embodiment as well, the respective layers stacked on the surface of aluminum-containing nitride intermediate layer 2 can have low dislocation density and excellent crystallinity. Therefore, the nitride semiconductor transistor element of the third embodiment can achieve improved characteristics such as electron mobility.

### EXAMPLES

### Experimental Example 1

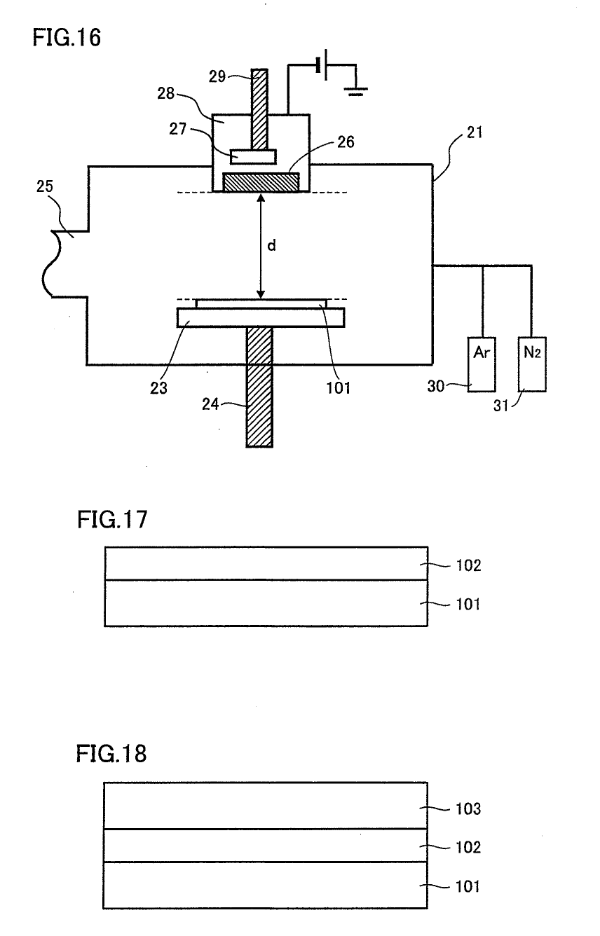

First, a sapphire substrate 101 shown in a schematic cross-sectional view in FIG. 15 was placed on heater 23 inside chamber 21 of the DC magnetron sputtering apparatus shown in FIG. 16 for applying a voltage by means of the DC-continuous scheme.

Sapphire substrate 101 was placed such that the c plane of sapphire substrate 101 faced the surface of Al target 26 and shortest distance d between the center of the surface of Al target 26 and the c plane of sapphire substrate 101 was set to 50 mm. Thereafter, sapphire substrate 101 was heated to the temperature of 500° C. by heater 23.

Next, only the nitrogen gas was supplied into chamber 21 of the DC magnetron sputtering apparatus at a flow rate of 20 sccm, and then, sapphire substrate 101 was maintained at the temperature of 500° C.

Then, a bias voltage of 3000 W was applied between sapphire substrate 101 and Al target 26 by means of the DC-continuous scheme to generate nitrogen plasma. Subsequently, the pressure within chamber 21 was kept at 0.5 Pa and the nitrogen gas (the volume ratio of the nitrogen gas to the entire gas was 100%) was supplied into chamber 21 at a flow rate of 20 sccm. As a result, as shown in a schematic cross-sectional view in FIG. 17, an AlN buffer layer 102 formed of the aggregate of columnar crystals of aluminum nitride (AlN) and having a thickness of 25 nm was stacked on the c plane of sapphire substrate 101 by reactive sputtering through the use of the DC magnetron sputtering method in which a voltage is applied by means of the DC-continuous scheme. The formation speed of AlN buffer layer 102 at this time was 0.04 nm/sec.

It is noted that magnet 27 in cathode 28 of the DC magnetron sputtering apparatus shown in FIG. 16 swung both during nitriding of the c plane of sapphire substrate 101 and during stacking of AlN buffer layer 102. In addition, stacking of AlN buffer layer 102 was performed for a prescribed time period in accordance with the film formation speed of AlN buffer layer 102 that was measured in advance. When the thickness of AlN buffer layer 102 reached 25 nm, the nitrogen plasma was stopped and the temperature of sapphire substrate 101 was reduced. The pressure within chamber 21 immediately before sputtering was 1×10⁻⁴ Pa or less.

Next, sapphire substrate 101 having AlN buffer layer 102 stacked thereon was taken out from chamber 21 of the DC magnetron sputtering apparatus, and was placed inside the reactor of the MOCVD apparatus. Sapphire substrate 101 having AlN buffer layer 102 stacked thereon was placed on a susceptor made of graphite for heating by a high-frequency induction heating-type heater. It is noted that when sapphire substrate 101 having AlN buffer layer 102 stacked thereon is heated by a resistive heating-type heater, sapphire substrate 101 having AlN buffer layer 102 stacked thereon is placed on a tray made of quartz that is placed on the susceptor made of graphite.

Thereafter, while the ammonia gas as well as the nitrogen gas and the hydrogen gas as carrier gases were supplied into the reactor, the temperature of sapphire substrate 101 was raised to 1125° C. for about 15 minutes. At this time, the pressure within the reactor was set to the normal pressure and the flow rate ratio of the hydrogen gas and the nitrogen gas (the flow rate of the hydrogen gas/the flow rate of the nitrogen gas) serving as the carrier gases was set to 50/50. After it was confirmed that the temperature of sapphire substrate 101 became stable at 1125° C., supply of the TMG gas into the reactor started, and a GaN underlying layer 103 made of undoped GaN and having a thickness of 5 μm was stacked on the surface of AlN buffer layer 102 by using the MOCVD method as shown in a schematic cross-sectional view in FIG. 18. It is noted that the ammonia gas was supplied into the reactor such that the mole ratio of the V group element to the III group element (the number of moles of the V group element/the number of moles of the III element) was set to 1500.

Thereafter, sapphire substrate 101 having GaN underlying layer 103 stacked thereon was taken out from the reactor. Then, an X-ray rocking curve of GaN underlying layer 103 was measured by using a thin film X-ray diff action method, and based on the X-ray rocking curve, a half value width (arcsec) of the X-ray rocking curve in a (004) plane of GaN underlying layer 103 was calculated. The result is shown in Table 1. As shown in Table 1, the half value with of the X-ray rocking curve in the (004) plane of GaN underlying layer 103 in Experimental Example 1 was 382 (arcsec).

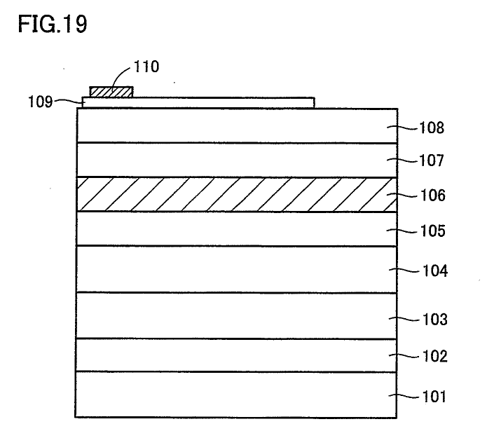

Next, the temperature of sapphire substrate 101 was set to 1125° C. and the silane gas was supplied into the reactor such that the doping concentration of Si was set to 1×10¹⁹/cm³. As a result, as shown in a schematic cross-sectional view in FIG. 19, a Si-doped n-type GaN contact layer 104 having a thickness of 3 μm was stacked on a surface of GaN underlying layer 103 by using the MOCVD method.

Next, after the supply of the TMG gas and the hydrogen gas into the reactor was stopped, the temperature of sapphire substrate 101 was reduced to 800° C. Then, after it was confirmed that the condition within the reactor became stable, the TMG gas, the TMI gas and the ammonia gas as material gases were supplied into the reactor. Furthermore, the silane gas was supplied into the reactor such that the doping concentration of Si was set to 1×10¹⁸/cm³. As a result, as shown in FIG. 19, a Si-doped n-type In_{0.01}Ga_{0.99}N barrier layer 105 having a thickness of 8 nm was stacked on a surface of n-type GaN contact layer 104.

Next, after the supply of the silane gas was stopped, the TMG gas and the TMI gas were supplied. As a result, a quantum well layer made of In_{0.1}Ga_{0.9}N and having a thickness of 3 nm was stacked.

By repeating the procedure for forming the quantum barrier layer and the quantum well layer as described above, as shown in FIG. 19, an MQW active layer 106 having a multiple quantum well structure in which the seven-layer quantum barrier layer made of n-type GaN and the six-layer quantum well layer made of In_{0.1}Ga_{0.9}N were alternately stacked one by one was stacked on a surface of n-type In_{0.01}Ga_{0.99}N barrier layer 105.

Next, the temperature of sapphire substrate 101 was raised to 1100° C., and the carrier gas was changed from the nitrogen gas to the hydrogen gas. The TMG gas, the TMA gas and the CP₂Mg gas were supplied into the reactor for two minutes, and then, the supply of the TMG gas and the TMA gas was stopped. As a result, as shown in FIG. 19, a Mg-doped p-type Al_{0.2}Ga_{0.8}N clad layer 107 having a thickness of 20 nm was stacked on a surface of MQW active layer 106.

Next, the temperature of sapphire substrate 101 was kept at 1100° C., and the supply of the TMA gas was stopped while the ammonia gas was supplied into the reactor. Thereafter, the amount of supply of the TMG gas and the CP₂Mg gas into the reactor was changed. As a result, as shown in FIG. 19, a Mg-doped p-type GaN contact layer 108 having a thickness of 0.2 μm was stacked on a surface of p-type Al_{0.2}Ga_{0.8}N clad layer 107.

After p-type GaN contact layer 108 was stacked, a current passing through the heater was stopped immediately and the carrier gas supplied into the reactor was changed from the hydrogen gas to the nitrogen gas. Then, after it was confirmed that the temperature of sapphire substrate 101 reached 300° C. or less, sapphire substrate 101 having the above layers stacked thereon was taken out from the reactor.

Next, as shown in FIG. 19, an ITO layer 109 was formed on a surface of p-type GaN contact layer 108, and then, a titanium layer, an aluminum layer and a gold layer were stacked in this order on a surface of ITO layer 109. As a result, a p-side bonding pad electrode 110 was formed.

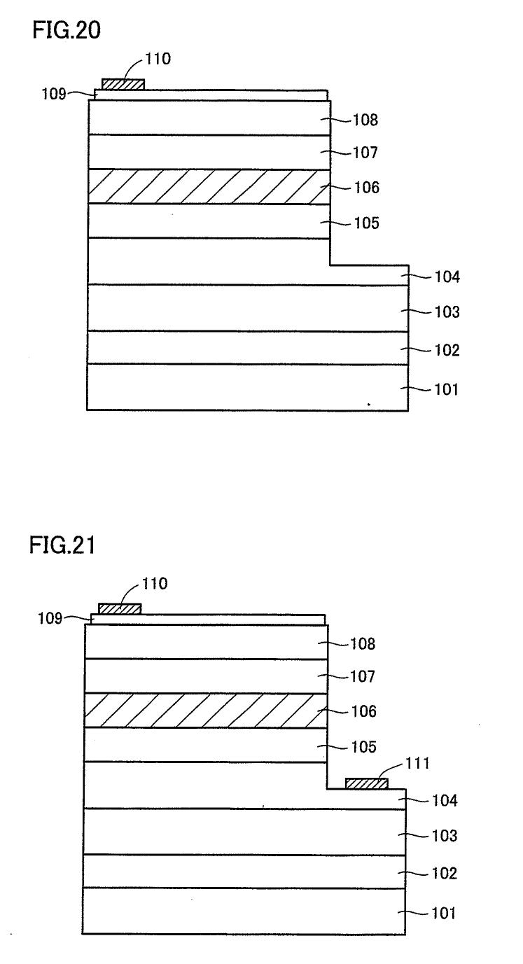

Next, as shown in a schematic cross-sectional view in FIG. 20, a part of the stacked body having p-side bonding pad electrode 110 formed thereon was removed by dry etching to expose a part of the surface of n-type GaN contact layer 104.

Thereafter, as shown in a schematic cross-sectional view in FIG. 21, a nickel layer, an aluminum layer, a titanium layer, and a gold layer were stacked in this order on the exposed surface of n-type GaN contact layer 104. As a result, an n-side bonding pad electrode 111 was formed.

A back surface of sapphire substrate 101 was ground and polished to achieve a mirror-like surface, and then, sapphire substrate 101 was split into a square chip of 350 μm per side. As a result, the nitride semiconductor light-emitting diode element of Experimental Example 1 was fabricated.

A forward current of 20 mA was applied between p-side bonding pad electrode 110 and n-side bonding pad electrode 111 of the nitride semiconductor light-emitting diode element of Experimental Example 1 fabricated as described above. A forward voltage in the forward current of 20 mA was 3.3 V. It is noted that this forward voltage corresponds to the operation voltage of the nitride semiconductor light-emitting diode element. In addition, light emission by the nitride semiconductor light-emitting diode element of Experimental Example 1 through ITO layer 109 was observed. The light emission wavelength was 445 nm and the light emission output was 22.3 mW. These results are shown in Table 1.

### Experimental Examples 2 to 8

In Experimental Examples 2 to 8, AlN buffer layer 102 and GaN underlying layer 103 were formed and the half value width (arcsec) of the X-ray rocking curve in the (004) plane of GaN underlying layer 103 was calculated similarly to Experimental Example 1 except that shortest distance d between the center of the surface of Al target 26 and the c plane of sapphire substrate 101 was set to 75 mm (Experimental Example 2), 100 mm (Experimental Example 3), 150 mm (Experimental Example 4), 180 mm (Experimental Example 5), 210 mm (Experimental Example 6), 250 mm (Experimental Example 7), and 280 mm (Experimental Example 8), respectively. The result is shown in Table 1. As shown in Table 1, the half value width (arcsec) of the X-ray rocking curve in the (004) plane of GaN underlying layer 103 in each of Experimental Examples 2 to 8 was 273 (Experimental Example 2), 42 (Experimental Example 3), 40 (Experimental Example 4), 34 (Experimental Example 5), 40 (Experimental Example 6), 50 (Experimental Example 7), and 242 (Experimental Example 8).

In addition, in each of Experimental Examples 2 to 8, the nitride semiconductor light-emitting diode element (the nitride semiconductor light-emitting diode elements of Experimental Examples 2 to 8) was fabricated similarly to Experimental Example 1 except for the above change. The forward voltage in the forward current of 20 mA, the light emission wavelength and the light emission output were measured for each of the nitride semiconductor light-emitting diode elements of Experimental Examples 2 to 8. The result is shown in Table 1.

As shown in Table 1, the forward voltage in the forward current of 20 mA of each of the nitride semiconductor light-emitting diode elements of Experimental Examples 2 to 8 was 3.2 V (Experimental Example 2), 3.0 V (Experimental Example 3), 2.9 V (Experimental Example 4), 2.9 V (Experimental Example 5), 3.0 V (Experimental Example 6), 3.0 V (Experimental Example 7), and 3.2 V (Experimental Example 8).

In addition, as shown in Table 1, the light emission wavelength of each of the nitride semiconductor light-emitting diode elements of Experimental Examples 2 to 8 was 447 nm (Experimental Example 2), 448 nm (Experimental Example 3), 445 nm (Experimental Example 4), 448 nm (Experimental Example 5), 447 nm (Experimental Example 6), 448 nm (Experimental Example 7), and 450 nm (Experimental Example 8).

Furthermore, as shown in table 1, the light emission output of each of the nitride semiconductor light-emitting diode elements of Experimental Examples 2 to 8 was 23.8 mW (Experimental Example 2), 25.0 mW (Experimental Example 3), 25.8 mW (Experimental Example 4), 25.5 mW (Experimental Example 5), 25.1 mW (Experimental Example 6), 24.8 mW (Experimental Example 7), and 23.1 mW (Experimental Example 8).

### Experimental Examples 9 to 12

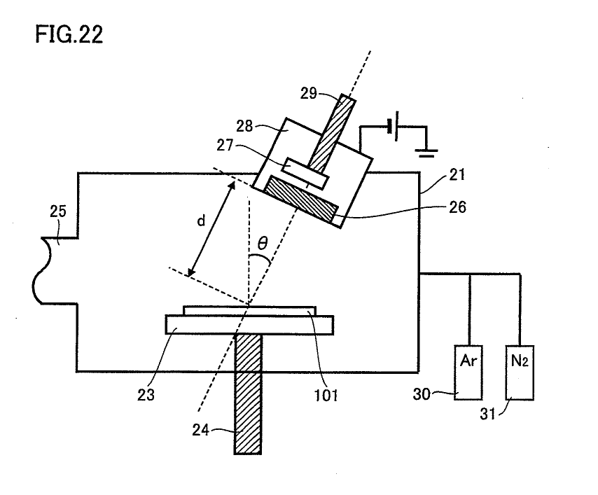

In Experimental Examples 9 to 12, AlN buffer layer 102 and GaN underlying layer 103 were formed by using a DC magnetron sputtering apparatus having a configuration shown in FIG. 22 for applying a voltage by means of the DC-continuous scheme and the half value width (arcsec) of the X-ray rocking curve in the (004) plane of GaN underlying layer 103 was calculated similarly to Experimental Example 1 except that inclination angle θ of the Al target with respect to the direction normal to the c plane of sapphire substrate 101 was set to 10° (Experimental Example 9), 20° (Experimental Example 10), 45° (Experimental Example 11), and 50° (Experimental Example 12), respectively. The result is shown in Table 1. As shown in Table 1, the half value width (arcsec) of the X-ray rocking curve in the (004) plane of GaN underlying layer 103 in each of Experimental Examples 9 to 12 was 40 (Experimental Example 9), 33 (Experimental Example 10), 35 (Experimental Example 11), and 180 (Experimental Example 12).

In addition, in each of Experimental Examples 9 to 12, the nitride semiconductor light-emitting diode element (the nitride semiconductor light-emitting diode elements of Experimental Examples 9 to 12) was fabricated similarly to Experimental Example 1 except for the above change. The forward voltage in the forward current of 20 mA, the light emission wavelength and the light emission output were measured for each of the nitride semiconductor light-emitting diode elements of Experimental Examples 9 to 12. The result is shown in Table 1.

As shown in Table 1, the forward voltage in the forward current of 20 mA of each of the nitride semiconductor light-emitting diode elements of Experimental Examples 9 to 12 was 3.0 V (Experimental Example 9), 2.9 V (Experimental Example 10), 3.0 V (Experimental Example 11), and 3.2 V (Experimental Example 12).

In addition, as shown in Table 1, the light emission wavelength of each of the nitride semiconductor light-emitting diode elements of Experimental Examples 9 to 12 was 449 nm (Experimental Example 9), 451 nm (Experimental Example 10), 448 nm (Experimental Example 11), and 447 nm (Experimental Example 12).

Furthermore, as shown in Table 1, the light emission output of each of the nitride semiconductor light-emitting diode elements of Experimental Examples 9 to 12 was 25.0 mW (Experimental Example 9), 25.6 mW (Experimental Example 10), 24.8 mW (Experimental Example 11), and 22.2 mW (Experimental Example 12).

### Experimental Examples 13 to 15

In Experimental Examples 13 to 15, AlN buffer layer 102 and GaN underlying layer 103 were formed and the half value width (arcsec) of the X-ray rocking curve in the (004) plane of GaN underlying layer 103 was calculated similarly to Experimental Example 1 except that the gas supplied into chamber 21 shown in FIG. 16 was changed to the mixed gas of the nitrogen gas and the argon gas. The result is shown in Table 1. It is noted that, in each of Experimental Examples 13 to 15, the volume ratio of the nitrogen gas (the ratio of nitrogen) to the gas supplied into chamber 21 was 75% (Experimental Example 13), 50% (Experimental Example 14) and 25% (Experimental Example 15). As shown in Table 1, the half value width (arcsec) of the X-ray rocking curve in the (004) plane of GaN underlying layer 103 in each of Experimental Examples 13 to 15 was 77 (Experimental Example 13), 222 (Experimental Example 14) and 422 (Experimental Example 15).

In addition, in each of Experimental Examples 13 to 15, the nitride semiconductor light-emitting diode element (the nitride semiconductor light-emitting diode elements of Experimental Examples 13 to 15) was fabricated similarly to Experimental Example 1 except for the above change. The forward voltage in the forward current of 20 mA, the light emission wavelength and the light emission output were measured for each of the nitride semiconductor light-emitting diode elements of Experimental Examples 13 to 15. The result is shown in Table 1.

As shown in Table 1, the forward voltage in the forward current of 20 mA of each of the nitride semiconductor light-emitting diode elements of Experimental Examples 13 to 15 was 3.1 V (Experimental Example 13), 3.2 V (Experimental Example 14) and 3.3 V (Experimental Example 15).

In addition, as shown in Table 1, the light emission wavelength of each of the nitride semiconductor light-emitting diode elements of Experimental Examples 13 to 15 was 447 nm (Experimental Example 13), 448 nm (Experimental Example 14) and 449 nm (Experimental Example 15).

Furthermore, as shown in Table 1, the light emission output of each of the nitride semiconductor light-emitting diode elements of Experimental Examples 13 to 15 was 24.3 mW (Experimental Example 13), 22.1 mW (Experimental Example 14) and 21.5 mW (Experimental Example 15).

TABLE 1

| | | | | | | GaN | | | |
|---|---|---|---|---|---|---|---|---|---|
| | | | | | | Underlying | Characteristics of Nitride Semiconductor | | |
| | Sputtering Conditions for AlN Buffer Layer | | | | | Layer | Light-Emitting Diode Element | | |
| | Shortest | Gas Flow Rate [sccm] | | Nitrogen | Inclination | Half Value | Forward | Light Emission | Light Emission |
| | Distance d | Nitrogen | | Ratio | Angle θ | Width | Voltage | Wavelength | Output |
| | [mm] | Gas | Argon Gas | [%] | [°] | [arcsec] | [V] | [nm] | [mW] |
| Experimental | 50 | 20 | 0 | 100 | 0 | 382 | 3.3 | 445 | 22.3 |
| Example 1 | | | | | | | | | |
| Experimental | 75 | 20 | 0 | 100 | 0 | 273 | 3.2 | 447 | 23.8 |
| Example 2 | | | | | | | | | |
| Experimental | 100 | 20 | 0 | 100 | 0 | 42 | 3.0 | 448 | 25.0 |
| Example 3 | | | | | | | | | |
| Experimental | 150 | 20 | 0 | 100 | 0 | 40 | 2.9 | 445 | 25.8 |
| Example 4 | | | | | | | | | |
| Experimental | 180 | 20 | 0 | 100 | 0 | 34 | 2.9 | 448 | 25.5 |
| Example 5 | | | | | | | | | |
| Experimental | 210 | 20 | 0 | 100 | 0 | 40 | 3.0 | 447 | 25.1 |
| Example 6 | | | | | | | | | |
| Experimental | 250 | 20 | 0 | 100 | 0 | 50 | 3.0 | 448 | 24.8 |
| Example 7 | | | | | | | | | |
| Experimental | 280 | 20 | 0 | 100 | 0 | 242 | 3.2 | 450 | 23.1 |
| Example 8 | | | | | | | | | |
| Experimental | 180 | 20 | 0 | 100 | 10 | 40 | 3.0 | 449 | 25.0 |
| Example 9 | | | | | | | | | |
| Experimental | 180 | 20 | 0 | 100 | 20 | 33 | 2.9 | 451 | 25.6 |
| Example 10 | | | | | | | | | |
| Experimental | 180 | 20 | 0 | 100 | 45 | 35 | 3.0 | 448 | 24.8 |
| Example 11 | | | | | | | | | |
| Experimental | 180 | 20 | 0 | 100 | 50 | 180 | 3.2 | 447 | 22.2 |
| Example 12 | | | | | | | | | |
| Experimental | 150 | 15 | 5 | 75 | 0 | 77 | 3.1 | 447 | 24.3 |
| Example 13 | | | | | | | | | |
| Experimental | 150 | 10 | 10 | 50 | 0 | 222 | 3.2 | 448 | 22.1 |
| Example 14 | | | | | | | | | |
| Experimental | 150 | 5 | 15 | 25 | 0 | 422 | 3.3 | 449 | 21.5 |
| Example 15 | | | | | | | | | |

(Evaluation)

As shown in Table 1, in Experimental Examples 3 to 7 in which shortest distance d (mm) between the center of the surface of Al target 26 and the c plane of sapphire substrate 101 was within the range of 100 mm or more and 250 mm or less, the half value width (arcsec) of the X-ray rocking curve in the (004) plane of GaN underlying layer 103 was extremely narrow, as compared with Experimental Examples 1, 2 and 8 in which shortest distance d was outside this range. Therefore, it was found that GaN underlying layer 103 having excellent crystallinity was obtained and the nitride semiconductor light-emitting diode element having excellent characteristics of low forward voltage and high light emission output was obtained.

In addition, as shown in Table 1, in Experimental Examples 4 to 6 in which above shortest distance d (mm) was within the range of 150 mm or more and 210 mm or less, the half value width (arcsec) of the X-ray rocking curve in the (004) plane of GaN underlying layer 103 was narrow, as compared with Experimental Examples 3 and 7 in which shortest distance d was outside this range. Therefore, it was found that GaN underlying layer 103 having excellent crystallinity was obtained and the nitride semiconductor light-emitting diode element having excellent characteristics of low forward voltage and high light emission output was obtained.

Furthermore, as shown in Table 1, in Experimental Examples 4 and 5 in which above shortest distance d (mm) was within the range of 150 mm or more and 180 mm or less, the half value width (arcsec) of the X-ray rocking curve in the (004) plane of GaN underlying layer 103 was narrow, as compared with Experimental Example 6 in which shortest distance d was outside this range. Therefore, it was found that GaN underlying layer 103 having excellent crystallinity was obtained and the nitride semiconductor light-emitting diode element having excellent characteristics of low forward voltage and high light emission output was obtained.

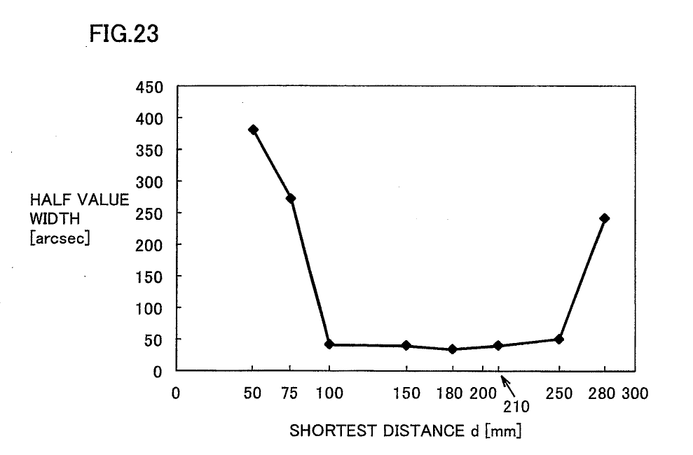

FIG. 23 illustrates the relationship between the half value width (arcsec) of the X-ray rocking curve in the (004) plane of GaN underlying layer 103 and shortest distance d (mm) between the center of the surface of Al target 26 and the c plane of sapphire substrate 101 in Experimental Examples 1 to 8. It is noted that, in FIG. 23, the vertical axis indicates the half value width (arcsec) of the X-ray rocking curve in the (004) plane of GaN underlying layer 103, and the horizontal axis indicates shortest distance d (mm) between the center of the surface of Al target 26 and the c plane of sapphire substrate 101.

As shown in FIG. 23, when shortest distance d between the center of the surface of Al target 26 and the c plane of sapphire substrate 101 was within the range of 100 mm or more and 250 mm or less, the half value width (arcsec) of the X-ray rocking curve in the (004) plane of GaN underlying layer 103 was extremely narrow. Therefore, it was found that GaN underlying layer 103 had significantly excellent crystallinity.

In addition, as shown in FIG. 23, it was found that for the purpose of further enhancing the crystallinity of GaN underlying layer 103, above shortest distance d was preferably set to the range of 150 mm or more and 210 mm or less, and particularly preferably 150 mm or more and 180 mm or less, such that the half value width (arcsec) of the X-ray rocking curve in the (004) plane of GaN underlying layer 103 became more narrow.

Furthermore, as shown in Table 1, in Experimental Examples 9 to 11 in which inclination angle θ of the Al target with respect to the direction normal to the c plane of sapphire substrate 101 was within the range of 10° or more and 45° or less, the half value width (arcsec) of the X-ray rocking curve in the (004) plane of GaN underlying layer 103 was extremely narrow, as compared with Experimental Example 12 in which inclination angle θ was 50°. Therefore, it was found that GaN underlying layer 103 having excellent crystallinity was obtained and the nitride semiconductor light-emitting diode element having excellent characteristics of low forward voltage and high light emission output was obtained.

Moreover, as shown in Table 1, in Experimental Examples 10 and 11 in which inclination angle θ of the Al target with respect to the direction normal to the c plane of sapphire substrate 101 was within the range of 20° or more and 45° or less, the half value width (arcsec) of the X-ray rocking curve in the (004) plane of GaN underlying layer 103 was narrow, as compared with Experimental Example 9 in which inclination angle θ was 10°. Therefore, it was found that GaN underlying layer 103 having excellent crystallinity was obtained and the nitride semiconductor light-emitting diode element having excellent characteristics of low forward voltage and high light emission output was obtained.

Additionally, as shown in Table 1, in Experimental Examples 4, 13 and 14 in which the ratio of nitrogen in the gas supplied into chamber 21 was within the range of 50% or more, the half value width (arcsec) of the X-ray rocking curve in the (004) plane of GaN underlying layer 103 was narrow, as compared with Experimental Example 15 in which the ratio of nitrogen was not within the range. Therefore, it was found that GaN underlying layer 103 having excellent crystallinity was obtained and the nitride semiconductor light-emitting diode element having excellent characteristics of low forward voltage and high light emission output was obtained.

In addition, as shown in Table 1, in Experimental Examples 4 and 13 in which the ratio of nitrogen in the gas supplied into chamber 21 was within the range of 75% or more, the half value width (arcsec) of the X-ray rocking curve in the (004) plane of GaN underlying layer 103 was narrow, as compared with Experimental Example 14 in which the ratio of nitrogen was not within the range. Therefore, it was found that GaN underlying layer 103 having excellent crystallinity was obtained and the nitride semiconductor light-emitting diode element having excellent characteristics of low forward voltage and high light emission output was obtained.

Furthermore, as shown in Table 1, in Experimental Example 4 in which the ratio of nitrogen in the gas supplied into chamber 21 was 100%, the half value width (arcsec) of the X-ray rocking curve in the (004) plane of GaN underlying layer 103 was narrow, as compared with Experimental Example 13 in which the ratio of nitrogen was not 100%. Therefore, it was found that GaN underlying layer 103 having excellent crystallinity was obtained and the nitride semiconductor light-emitting diode element having excellent characteristics of low forward voltage and high light emission output was obtained.

Although the present invention has been described and illustrated in detail, it is clearly understood that the same is by way of illustration and example only and is not to be taken by way of limitation, the scope of the present invention being interpreted by the terms of the appended claims.

The present invention is applicable to a method for manufacturing an aluminum-containing nitride intermediate layer, a method for manufacturing a nitride layer, and a method for manufacturing a nitride semiconductor element. In particular, the present invention can be suitably applicable to the manufacture of a nitride semiconductor light-emitting diode element, a nitride semiconductor laser element, a nitride semiconductor transistor element and the like by using a III group nitride semiconductor.

What is claimed is:

1. A method for manufacturing an aluminum-containing nitride intermediate layer, comprising the steps of:
arranging a substrate and a target containing aluminum to have a distance of 100 mm or more and 250 mm or less between said substrate and said target; and
forming an aluminum-containing nitride intermediate layer on a surface of said substrate by using a DC magnetron sputtering method in which a voltage is applied between said substrate and said target by means of a DC-continuous scheme.

2. The method for manufacturing an aluminum-containing nitride intermediate layer according to claim 1, further comprising the step of
between the step of arranging said substrate and said target and the step of forming said aluminum-containing nitride intermediate layer, introducing nitrogen gas between said substrate and said target.

3. The method for manufacturing an aluminum-containing nitride intermediate layer according to claim 1, wherein
in the step of arranging said substrate and said target, said substrate and said target are arranged such that said target is inclined with respect to said substrate.

4. A method for manufacturing an aluminum-containing nitride intermediate layer, comprising the steps of:
arranging a substrate and a target containing aluminum to have a spacing between said substrate and said target;
introducing nitrogen gas between said substrate and said target; and
forming an aluminum-containing nitride intermediate layer on a surface of said substrate by using a DC magnetron sputtering method in which a voltage is applied between said substrate and said target by means of a DC-continuous scheme.

5. The method for manufacturing an aluminum-containing nitride intermediate layer according to claim 4, wherein
in the step of arranging said substrate and said target, said substrate and said target are arranged such that said target is inclined with respect to said substrate.

6. A method for manufacturing an aluminum-containing nitride intermediate layer, comprising the steps of:
arranging a substrate and a target containing aluminum to have a spacing between said substrate and said target and to incline said target with respect to said substrate; and
forming an aluminum-containing nitride intermediate layer on a surface of said substrate by using a DC magnetron sputtering method in which a voltage is applied between said substrate and said target by means of a DC-continuous scheme.

7. A method for manufacturing a nitride layer, comprising the steps of:
arranging a substrate and a target containing aluminum to have a distance of 100 mm or more and 250 mm or less between said substrate and said target;
forming an aluminum-containing nitride intermediate layer on a surface of said substrate by using a DC magnetron sputtering method in which a voltage is applied between said substrate and said target by means of a DC-continuous scheme; and
forming a nitride layer on said aluminum-containing nitride intermediate layer.

8. The method for manufacturing a nitride layer according to claim 7, further comprising the step of
between the step of arranging said substrate and said target and the step of forming said aluminum-containing nitride intermediate layer, introducing nitrogen gas between said substrate and said target.

9. The method for manufacturing a nitride layer according to claim 7, wherein
in the step of arranging said substrate and said target, said substrate and said target are arranged such that said target is inclined with respect to said substrate.

10. A method for manufacturing a nitride layer, comprising the steps of:
arranging a substrate and a target containing aluminum to have a spacing between said substrate and said target;
introducing nitrogen gas between said substrate and said target;
forming an aluminum-containing nitride intermediate layer on a surface of said substrate by using a DC magnetron sputtering method in which a voltage is applied between said substrate and said target by means of a DC-continuous scheme; and
forming a nitride layer on said aluminum-containing nitride intermediate layer.

11. The method for manufacturing a nitride layer according to claim 10, wherein
in the step of arranging said substrate and said target, said substrate and said target are arranged such that said target is inclined with respect to said substrate.

12. A method for manufacturing a nitride layer, comprising the steps of:
arranging a substrate and a target containing aluminum to have a spacing between said substrate and said target and to incline said target with respect to said substrate;
forming an aluminum-containing nitride intermediate layer on a surface of said substrate by using a DC magnetron sputtering method in which a voltage is applied between said substrate and said target by means of a DC-continuous scheme; and
forming a nitride layer on said aluminum-containing nitride intermediate layer.

13. A method for manufacturing a nitride semiconductor element, comprising the steps of:
arranging a substrate and a target containing aluminum to have a distance of 100 mm or more and 250 mm or less between said substrate and said target;
forming an aluminum-containing nitride intermediate layer on a surface of said substrate by using a DC magnetron sputtering method in which a voltage is applied between said substrate and said target by means of a DC-continuous scheme; and
forming a nitride semiconductor layer on said aluminum-containing nitride intermediate layer.

14. The method for manufacturing a nitride semiconductor element according to claim 13, further comprising the step of
between the step of arranging said substrate and said target and the step of forming said aluminum-containing nitride intermediate layer, introducing nitrogen gas between said substrate and said target.

15. The method for manufacturing a nitride semiconductor element according to claim 13, wherein
in the step of arranging said substrate and said target, said substrate and said target are arranged such that said target is inclined with respect to said substrate.

16. A method for manufacturing a nitride semiconductor element, comprising the steps of:
arranging a substrate and a target containing aluminum to have a spacing between said substrate and said target;
introducing nitrogen gas between said substrate and said target;
forming an aluminum-containing nitride intermediate layer on a surface of said substrate by using a DC magnetron sputtering method in which a voltage is applied between said substrate and said target by means of a DC-continuous scheme; and
forming a nitride semiconductor layer on said aluminum-containing nitride intermediate layer.

17. The method for manufacturing a nitride semiconductor element according to claim 16, wherein
in the step of arranging said substrate and said target, said substrate and said target are arranged such that said target is inclined with respect to said substrate.

18. A method for manufacturing a nitride semiconductor element, comprising the steps of:
arranging a substrate and a target containing aluminum to have a spacing between said substrate and said target and to incline said target with respect to said substrate;
forming an aluminum-containing nitride intermediate layer on a surface of said substrate by using a DC magnetron sputtering method in which a voltage is applied between said substrate and said target by means of a DC-continuous scheme; and
forming a nitride semiconductor layer on said aluminum-containing nitride intermediate layer.
